(19) United States
(12) Patent Application Publication
(10) Pub. No.: US 2025/0336654 A1
(43) Pub. Date: Oct. 30, 2025

(54) PLASMA PROCESSING APPARATUS AND SUBSTRATE SUPPORT

(71) Applicant: Tokyo Electron Limited, Tokyo (JP)

(72) Inventors: Hajime TAMURA, Miyagi (JP); Takahiko SATO, Miyagi (JP); Masato TAKAYAMA, Miyagi (JP); Sho MURANO, Miyagi (JP)

(73) Assignee: Tokyo Electron Limited, Tokyo (JP)

(21) Appl. No.: 19/257,745

(22) Filed: Jul. 2, 2025

Related U.S. Application Data
(63) Continuation of application No. PCT/JP2024/000202, filed on Jan. 9, 2024.
(60) Provisional application No. 63/479,813, filed on Jan. 13, 2023.
(60) Provisional application No. 63/486,718, filed on Feb. 24, 2023.

(51) Int. Cl. H01J 37/32; H01L 21/683

(52) U.S. Cl. CPC H01J 37/32724; H01L 21/6833; H01J 2237/002; H01J 2237/2007

(57) ABSTRACT

A plasma processing apparatus includes: a plasma processing chamber, a base disposed in the plasma processing chamber, and an electrostatic chuck disposed on an upper surface of the base and having a support surface that supports at least one of a substrate and a ring assembly. The electrostatic chuck includes at least one conductive member, the electrostatic chuck is formed with at least one heat transfer gas supply hole having a diameter of 0.2 mm or less and penetrating from the support surface to a rear surface opposite to the support surface, and the at least one conductive member is disposed around at least a portion of the heat transfer gas supply hole.

### CROSS-REFERENCE TO RELATED APPLICATIONS

This application is a bypass continuation application of international application No. PCT/JP2024/000202 having an international filing date of Jan. 9, 2024 and designating the United States, the international application being based upon and claiming the benefit of priority from U.S. Ser. No. 63/479,813, filed on Jan. 13, 2023, and U.S. Ser. No. 63/486,718, filed on Feb. 24, 2023, the entire contents of each are incorporated herein by reference.

### TECHNICAL FIELD

The present disclosure relates to a plasma processing apparatus and a substrate support.

### BACKGROUND

Patent Document 1 discloses a plasma processing apparatus that includes a stage including a plate-shaped member formed with a first through-hole and a base formed with a second through-hole communicating with the first through-hole, and an embedded member disposed inside the first through-hole and the second through-hole. Patent Document 2 discloses a stage that includes a wafer stage formed with a first through-hole, a base formed with a second through-hole communicating with the first through-hole, and a sleeve provided inside the second through-hole.

### CITATION LIST

### Patent Documents

Patent Document 1: JP2019-149422A
Patent Document 2: JP2021-28958A

### SUMMARY

The technique according to the present disclosure prevents or reduces an abnormal discharge in a heat transfer gas flow path.

One aspect of the present disclosure provides a plasma processing apparatus. The plasma processing apparatus includes: a plasma processing chamber, a base disposed in the plasma processing chamber, and an electrostatic chuck disposed on an upper surface of the base and having a support surface that supports at least one of a substrate and a ring assembly. The electrostatic chuck includes at least one conductive member, the electrostatic chuck is formed with at least one heat transfer gas supply hole having a diameter of 0.2 mm or less and penetrating from the support surface to a rear surface opposite to the support surface, and the at least one conductive member is disposed around at least a portion of the heat transfer gas supply hole.

According to the present disclosure, an abnormal discharge in the heat transfer gas flow path can be prevented or reduced.

### BRIEF DESCRIPTION OF DRAWINGS

FIG. 1 is a diagram illustrating a configuration example of a plasma processing system according to an embodiment;

FIG. 2 is a cross-sectional view illustrating a configuration example of a plasma processing apparatus according to the embodiment;

FIG. 3 is a plan view schematically illustrating a configuration example of a main body according to a first embodiment;

FIG. 4 is a partial cross-sectional view schematically illustrating a configuration example of the main body according to the first embodiment;

FIG. 5 is a plan view illustrating an example of the number and disposition of heat transfer gas supply holes in a gas outlet;

FIG. 6 is a plan view illustrating another example of the number and disposition of the heat transfer gas supply holes in the gas outlet;

FIG. 7 is a partial cross-sectional view schematically illustrating a modification of the main body according to the first embodiment;

FIG. 8 is a partial cross-sectional view schematically illustrating a modification of the main body according to the first embodiment;

FIG. 9 is a partial cross-sectional view schematically illustrating a modification of the main body according to the first embodiment;

FIG. 10 is a partial cross-sectional view schematically illustrating a configuration example of a main body according to a second embodiment;

FIG. 11 is a partial cross-sectional view schematically illustrating a modification of the main body according to the second embodiment;

FIG. 12 is a partial cross-sectional view schematically illustrating a modification of the main body according to the second embodiment;

FIG. 13 is a partial cross-sectional view schematically illustrating a modification of the main body according to the second embodiment;

FIG. 14 is a partial cross-sectional view schematically illustrating a modification of the main body according to the second embodiment;

FIG. 15 is a partial cross-sectional view schematically illustrating a modification of the main body according to the second embodiment;

FIG. 16 is a plan view schematically illustrating a configuration example of a main body according to a third embodiment;

FIG. 17 is a partial cross-sectional view schematically illustrating a configuration example of the main body according to the third embodiment;

FIG. 18 is a partial cross-sectional view schematically illustrating a modification of the main body according to the third embodiment;

FIG. 19 is a plan view schematically illustrating a configuration example of a main body according to a fourth embodiment;

FIG. 20 is a partial cross-sectional view schematically illustrating a configuration example of the main body according to the fourth embodiment;

FIG. 21 is a partial cross-sectional view schematically illustrating a modification of the main body according to the fourth embodiment;

FIG. 22 is a partial cross-sectional view schematically illustrating a modification of the main body according to the fourth embodiment;

FIG. 23 is a plan view schematically illustrating a configuration example of a main body provided with a conductive embedded member according to a fifth embodiment;

FIG. 24 is a plan view schematically illustrating a configuration example of the conductive embedded member according to the fifth embodiment;

FIG. 25 is a cross-sectional view schematically illustrating a configuration example of the conductive embedded member according to the fifth embodiment;

FIG. 26 is a partial cross-sectional view schematically illustrating a configuration example of the main body provided with the conductive embedded member according to the fifth embodiment;

FIG. 27 is a plan view schematically illustrating a modification of the conductive embedded member according to the fifth embodiment;

FIG. 28 is a cross-sectional view schematically illustrating a modification of the conductive embedded member according to the fifth embodiment;

FIG. 29 is a plan view schematically illustrating a modification of the conductive embedded member according to the fifth embodiment;

FIG. 30 is a cross-sectional view schematically illustrating a modification of the conductive embedded member according to the fifth embodiment;

FIG. 31 is a partial cross-sectional view schematically illustrating a configuration example of a main body according to a sixth embodiment;

FIG. 32 is a partial cross-sectional view schematically illustrating a configuration example of a main body according to a seventh embodiment;

FIG. 33 is a partial cross-sectional view schematically illustrating a configuration example of a main body according to an eighth embodiment;

FIG. 34 is a partial cross-sectional view schematically illustrating a configuration example of a main body according to a ninth embodiment;

FIG. 35 is a partial cross-sectional view schematically illustrating a modification of the main body according to the ninth embodiment;

FIG. 36 is a plan view schematically illustrating a configuration example of a main body according to an eleventh embodiment;

FIG. 37 is a partial cross-sectional view schematically illustrating a configuration example of the main body according to the eleventh embodiment;

FIG. 38 is a partial cross-sectional view schematically illustrating a configuration example of a main body according to a twelfth embodiment;

FIG. 39 is a partial cross-sectional view schematically illustrating a modification of the main body according to the twelfth embodiment;

FIG. 40 is a partial cross-sectional view schematically illustrating a modification of the main body according to the twelfth embodiment;

FIG. 41 is a partial cross-sectional view schematically illustrating a modification of the main body according to the twelfth embodiment;

FIG. 42 is a partial cross-sectional view schematically illustrating a modification of the main body according to the twelfth embodiment;

FIG. 43 is a plan view schematically illustrating a configuration example of a main body according to a thirteenth embodiment;

FIG. 44 is a partial cross-sectional view schematically illustrating a configuration example of the main body according to the thirteenth embodiment;

FIG. 45 is a partial cross-sectional view schematically illustrating a modification of the main body according to the thirteenth embodiment;

FIG. 46 is a plan view schematically illustrating a configuration example of a main body according to a fourteenth embodiment;

FIG. 47 is a partial cross-sectional view schematically illustrating a configuration example of the main body according to the fourteenth embodiment;

FIG. 48 is a partial cross-sectional view schematically illustrating a modification of the main body according to the fourteenth embodiment;

FIG. 49 is a plan view schematically illustrating a configuration example of a main body provided with an embedded member according to a fifteenth embodiment;

FIG. 50 is a plan view schematically illustrating a configuration example of the embedded member according to the fifteenth embodiment;

FIG. 51 is a cross-sectional view schematically illustrating a configuration example of the embedded member according to the fifteenth embodiment;

FIG. 52 is a partial cross-sectional view schematically illustrating a configuration example of the main body provided with the embedded member according to the fifteenth embodiment;

FIG. 53 is a plan view schematically illustrating a modification of the embedded member according to the fifteenth embodiment;

FIG. 54 is a cross-sectional view schematically illustrating a modification of the embedded member according to the fifteenth embodiment;

FIG. 55 is a plan view schematically illustrating a modification of the embedded member according to the fifteenth embodiment; and

FIG. 56 is a cross-sectional view schematically illustrating a modification of the embedded member according to the fifteenth embodiment.

### DETAILED DESCRIPTION

In a process of manufacturing a semiconductor device, a semiconductor wafer (hereinafter referred to as a “substrate”) is placed on a substrate support disposed in a processing module, and various processing steps for performing desired processing on the substrate are performed. The substrate support includes an electrostatic chuck that holds the substrate. The electrostatic chuck is provided with a through-hole as a heat transfer gas flow path for supplying a heat transfer gas such as helium gas to a gap between a rear surface of the substrate and a front surface of the electrostatic chuck. An abnormal discharge may occur in a plasma process in a space inside such a through-hole.

In order to reduce such an abnormal discharge, Patent Document 1 discloses a substrate support in which an embedded member is provided in a through-hole and a heat transfer gas is supplied through a clearance between the embedded member and the through-hole. Patent Document 2 discloses a stage having a sleeve that is provided inside a through-hole (a second through-hole) provided in a base and forms a portion of the through-hole.

On the other hand, in the configuration in which the embedded member or the sleeve is simply provided in the through-hole as in Patent Document 1 or 2, it has been found that an unexpected error occurs in a space where an abnormal discharge may occur due to a dimensional tolerance, an installation position tolerance, radical consumption, or the like of the embedded member or the sleeve, and thus the abnormal discharge may be generated. From such a viewpoint, there is room for improvement in preventing or reducing the abnormal discharge in the through-hole.

Therefore, the technique according to the present disclosure prevents or reduces an abnormal discharge in a heat transfer gas flow path provided in a substrate support.

Hereinafter, a configuration of a substrate processing apparatus according to the present embodiment will be described with reference to the drawings. The same reference numerals will be given to elements having substantially the same functional configurations throughout the specification, and redundant description thereof will be omitted.

### <Plasma Processing System>

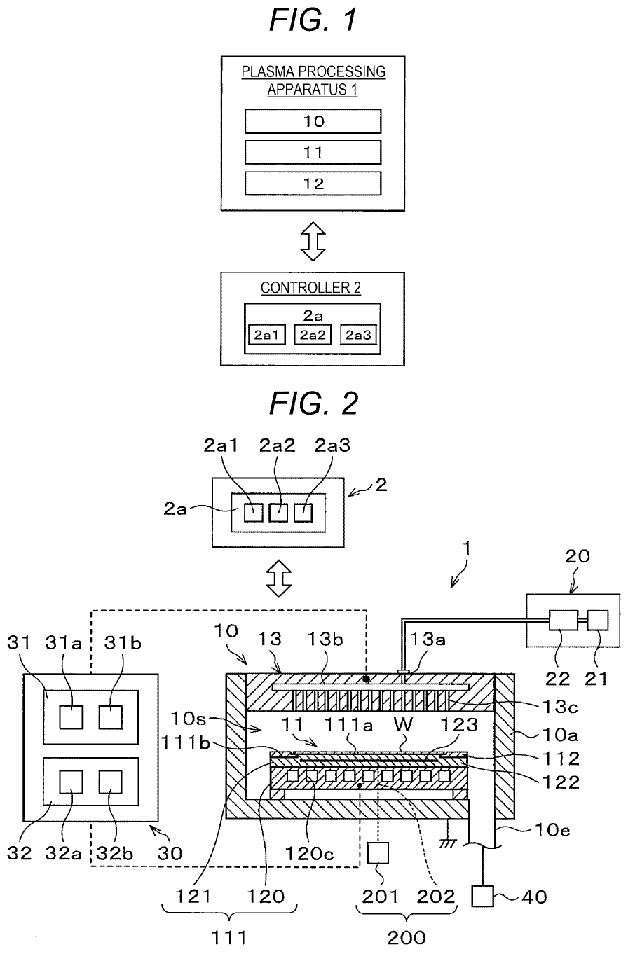

FIG. 1 is a diagram illustrating an example of a configuration of a plasma processing system. In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 has at least one gas supply port via which at least one processing gas is supplied into the plasma processing space, and at least one gas exhaust port via which the gas is exhausted from the plasma processing space. The gas supply port is connected to a gas supply 20, which will be described later, and the gas exhaust port is connected to an exhaust system 40, which will be described later. The substrate support 11 is disposed in the plasma processing space and has a substrate support surface for supporting the substrate. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

The plasma generator 12 is configured to generate plasma from at least one processing gas supplied into the plasma processing space. The plasma formed in the plasma processing space may be Capacitively Coupled Plasma (CCP), Inductively Coupled Plasma (ICP), Electron-Cyclotron-Resonance Plasma (ECR plasma), Helicon Wave Plasma (HWP), Surface Wave Plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 100 kHz to 150 MHz.

The controller 2 processes computer-executable instructions for instructing the plasma processing apparatus 1 to execute various steps described herein below. The controller 2 may be configured to control elements of the plasma processing apparatus 1 to execute the various steps described herein below. In one embodiment, part or all of the controller 2 may be in the plasma processing apparatus 1. The controller 2 may include a processor 2a1, a storage 2a2, and a communication interface 2a3. The controller 2 is implemented, for example, by a computer 2a. The processor 2al may be configured to read a program from the storage 2a2 and perform various control operations by executing the read program. The program may be stored in advance in the storage 2a2, or may be acquired via a medium when necessary. The acquired program is stored in the storage 2a2, read from the storage 2a2 by the processor 2al, and executed thereby. The medium may be any of various recording media readable by the computer 2a, or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

### <Plasma Processing Apparatus>

Hereinafter, an example of a configuration of a capacitively-coupled plasma processing apparatus as an example of the plasma processing apparatus 1 will be described. FIG. 2 is a diagram illustrating the example of the configuration of the capacitively-coupled plasma processing apparatus.

The capacitively-coupled plasma processing apparatus 1 includes the plasma processing chamber 10, the gas supply 20, a power source 30, and the exhaust system 40. The plasma processing apparatus 1 further includes the substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a portion of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from the housing of the plasma processing chamber 10.

The substrate support 11 includes a main body 111 and a ring assembly 112. The main body 111 has a central region 111a, which supports a substrate W, and an annular region 111b, which supports the ring assembly 112. A wafer is an example of the substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 so as to surround the substrate W on the central region 111a of the main body 111. Accordingly, the central region 111a has a substrate support surface for supporting the substrate W, and the annular region 111b has a ring support surface for supporting the ring assembly 112. In the present disclosure, the substrate support 11 may include only the main body 111. The substrate support 11 may include only an electrostatic chuck 121, which will be described later. In other words, in one embodiment, the electrostatic chuck 121, which will be described later, alone forms the substrate support 11 of the present disclosure.

The main body 111 includes a base 120 and the electrostatic chuck 121. The base 120 includes a conductive base 120a made of a conductive material. The conductive base 120a of the base 120 may function as a lower electrode. The electrostatic chuck 121 is disposed on an upper surface of the base 120. The electrostatic chuck 121 includes a dielectric member 122, an electrostatic electrode 123 disposed in the dielectric member 122, and a conductive member 124 at least partially disposed in the dielectric member 122. The dielectric member 122 has the central region 111a. In one embodiment, the dielectric member 122 also has the annular region 111b. Hereinafter, the substrate support surface of the central region 111a or the ring support surface of the annular region 111b in the electrostatic chuck 121 will be collectively referred to simply as a “support surface 121a”.

Other members that surround the electrostatic chuck 121, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 121 and the annular insulating member. At least one RF/DC electrode coupled to an RF power source 31 and/or a DC power source 32, which will be described later, may be disposed in the dielectric member 122. In this case, at least one RF/DC electrode functions as the lower electrode. When a bias RF signal and/or DC signal, which will be described later, is supplied to at least one RF/DC electrode, the RF/DC electrode is also referred to as a bias electrode. The conductive base 120a of the base 120 and at least one RF/DC electrode may function as lower electrodes. The electrostatic electrode 123 may function as the lower electrode. The substrate support 11 therefore includes at least one lower electrode.

The ring assembly 112 includes one or more annular members. In one embodiment, the one or more annular members include one or more edge rings and at least one cover ring. The edge ring is made of an electrically conductive material or an insulating material, and the cover ring is made of an insulating material.

The substrate support 11 may further include a heat transfer gas supply 200 configured to supply a heat transfer gas to a gap between a rear surface of the substrate W and the central region 111a. The heat transfer gas supply 200 supplies a heat transfer gas, such as helium gas, supplied from a heat transfer gas source 201 to a gap G through a heat transfer gas flow path 202 formed in the main body 111. The details of the heat transfer gas flow path 202 will be described later.

The substrate support 11 may include a temperature control module configured to adjust at least one of the electrostatic chuck 121, the ring assembly 112, and the substrate W to a target temperature. The temperature control module may include a heater, a heat transfer medium, a flow path 120c, or a combination thereof. A heat transfer fluid, such as brine or gas, flows through the flow path 120c. In one embodiment, the flow path 120c is formed in the base 120, and one or more heaters are disposed in the dielectric member 122 of the electrostatic chuck 121.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the gas introduction ports 13c. The shower head 13 further includes at least one upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. The flow rate controller 22 may include, for example, a mass flow controller or a pressure-controlled flow rate controller. Further, the gas supply 20 may include at least one flow rate modulation device that modulates or pulses a flow rate of at least one processing gas.

The power source 30 includes the RF power source 31 coupled to the plasma processing chamber 10 via at least one impedance matching circuit. The RF power source 31 is configured to supply at least one RF signal (RF power) to at least one lower electrode and/or at least one upper electrode. Plasma is thus generated from the at least one processing gas supplied into the plasma processing space 10s. Accordingly, the RF power source 31 may function as at least a part of the plasma generator 12. Supplying the bias RF signal to at least one lower electrode can generate a bias potential in the substrate W to attract an ionic component in the formed plasma to the substrate W.

In one embodiment, the RF power source 31 includes a first RF generator 31a and a second RF generator 31b. The first RF generator 31a is coupled to at least one lower electrode and/or at least one upper electrode via at least one impedance matching circuit, and is configured to generate a source RF signal (source RF power) for plasma generation. In one embodiment, the source RF signal has a frequency within a range from 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is coupled to the at least one lower electrode via the at least one impedance matching circuit and configured to generate the bias RF signal (bias RF power). A frequency of the bias RF signal may be the same as or different from a frequency of the source RF signal. In one embodiment, the bias RF signal has a frequency lower than the frequency of the source RF signal. In one embodiment, the bias RF signal has a frequency within a range from 100 kHz to 60 MHz. In one embodiment, the second RF generator 31b may be configured to generate a plurality of bias RF signals having different frequencies. The generated one or more bias RF signals are supplied to at least one lower electrode. In various embodiments, at least one of the source RF signal and the bias RF signal may be pulsed.

The power source 30 may include the DC power source 32 coupled to the plasma processing chamber 10. The DC power source 32 includes a first DC generator 32a and a second DC generator 32b. In one embodiment, the first DC generator 32a is connected to at least one lower electrode to generate a first DC signal. The generated first DC signal is applied to at least one lower electrode. In one embodiment, the second DC generator 32b is connected to at least one upper electrode and configured to generate a second DC signal. The generated second DC signal is applied to the at least one upper electrode.

In various embodiments, the first and second DC signals may be pulsed. In this case, a sequence of voltage pulses is applied to at least one lower electrode and/or at least one upper electrode. The voltage pulses may each have a rectangular, trapezoidal, or triangular pulse waveform or a combination thereof. In one embodiment, a waveform generator that generates the sequence of the voltage pulses from a DC signal is connected between the first DC generator 32a and at least one lower electrode. Accordingly, the first DC generator 32a and the waveform generator form a voltage pulse generator. When the second DC generator 32b and the waveform generator form a voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected, for example, to a gas exhaust port 10e disposed at a bottom of the plasma processing chamber 10. The exhaust system 40 may include a pressure adjusting valve and a vacuum pump. The pressure adjusting valve adjusts a pressure in the plasma processing space 10s. The vacuum pump may include a turbo molecular pump, a dry pump, or a combination thereof.

### <Heat Transfer Gas Flow Path>

### First Embodiment

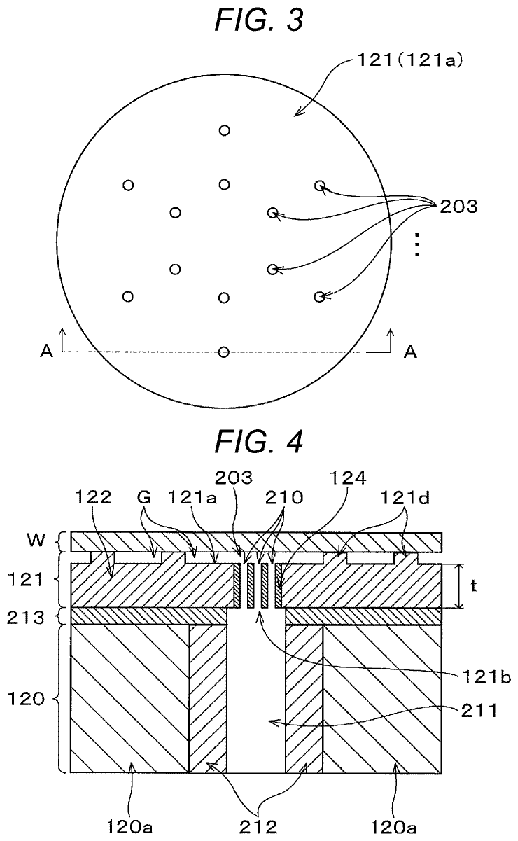

Hereinafter, a configuration example of the main body 111 according to a first embodiment will be described. FIG. 3 is a plan view schematically illustrating the configuration example of the main body 111 according to the first embodiment. FIG. 4 is a partial cross-sectional view taken perpendicular to the support surface 121a along a section A-A in FIG. 3, schematically illustrating the configuration example of the main body 111 according to the first embodiment.

In FIG. 3, at least one gas outlet 203 is provided on the support surface 121a of the electrostatic chuck 121. In the present embodiment, twelve gas outlets 203 are provided, and these gas outlets 203 are provided at rotationally symmetrical positions in a plan view of the electrostatic chuck 121.

In FIG. 4, one gas outlet 203 in the electrostatic chuck 121 is formed with at least one heat transfer gas supply hole 210 penetrating from the support surface 121a to a rear surface 121b opposite to the support surface 121a. At least one conductive member 124 is disposed around at least a portion of the heat transfer gas supply hole 210, and is disposed around an entirety of the heat transfer gas supply hole 210 in the present embodiment. Dots 121d are provided on the support surface 121a of the electrostatic chuck 121, and a gap G is formed between the substrate W and the electrostatic chuck 121 when the substrate W is placed on the dots 121d. In FIG. 3, the substrate W and the dots 121d are not illustrated.

The base 120 is formed with a base flow path 211 communicating with the heat transfer gas supply hole 210. The base flow path 211 is connected to the heat transfer gas supply hole 210 at one end and connected to the heat transfer gas source 201 at the other end. The base 120 also includes a sleeve 212. The conductive base 120a of the base 120 is insulated from the base flow path 211 by the sleeve 212. The sleeve 212 is formed of an insulating material and forms an inner wall of the base flow path 211. In one embodiment, the sleeve 212 is a substantially cylindrical member forming the base flow path 211 and is embedded in a through-hole provided in the conductive base 120a of the base 120.

An adhesive layer 213 is provided between the base 120 and the electrostatic chuck 121. The adhesive layer 213 is provided with a hole to connect and communicate the heat transfer gas supply hole 210 and the base flow path 211. In the present embodiment, the adhesive layer 213 has the hole having a diameter same as that of the base flow path 211. In one embodiment, the adhesive layer 213 is provided with the hole having a diameter same as that of the heat transfer gas supply hole 210 at a position corresponding to the heat transfer gas supply hole 210. The adhesive layer 213 is formed of, but is not limited to, a material having plasma resistance and heat resistance. The adhesive layer 213 is made of, for example, an acrylic resin, a silicone (silicon resin), or an epoxy resin.

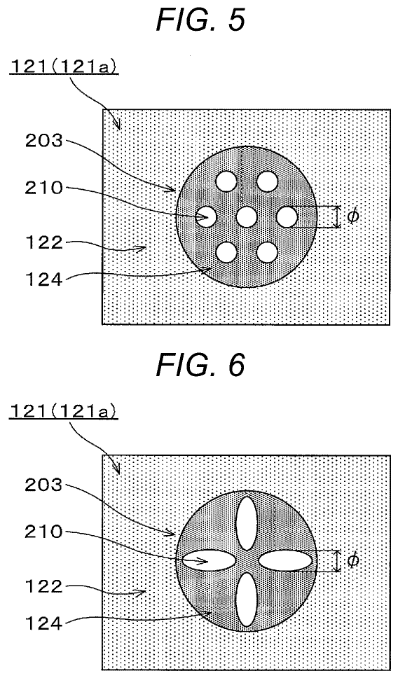

FIG. 5 is a plan view illustrating the number and disposition of the heat transfer gas supply holes 210 in the gas outlet 203. At least one heat transfer gas supply hole 210 is provided for each gas outlet 203, and in the present embodiment, seven heat transfer gas supply holes 210 are provided at rotationally symmetrical positions in the plan view of the electrostatic chuck 121. A cross-sectional shape of the heat transfer gas supply hole 210 is circular in a cross-section perpendicular to a flow path direction of the heat transfer gas supply hole 210.

The conductive member 124 disposed around the heat transfer gas supply hole 210 makes potential in a space inside the heat transfer gas supply hole 210 uniform, and makes the space as an electric field-free space. That is, the conductive member 124 forms an electric field-free space inside the heat transfer gas supply hole 210, thereby preventing or reducing an occurrence of abnormal discharge.

A diameter φ of the heat transfer gas supply hole 210 is a diameter of a circle in the cross-sectional shape, and is 0.5 mm or less. In one embodiment, the diameter φ of the heat transfer gas supply hole 210 is 0.2 mm or less. Accordingly, the occurrence of the abnormal discharge in the heat transfer gas supply hole 210 can be more effectively prevented or reduced. When the diameter φ of the heat transfer gas supply hole 210 is set to 0.2 mm or less, an aspect ratio of the heat transfer gas supply hole 210, which will be described later, may be set to 7 or more. The aspect ratio of the heat transfer gas supply hole 210 is a ratio (t/φ) of a thickness t of the electrostatic chuck 121 to the diameter φ of the heat transfer gas supply hole 210. The thickness t of the electrostatic chuck 121 refers to a distance from the support surface 121a to the rear surface 121b of the electrostatic chuck 121, excluding the dots 121d (see FIG. 3). As an example, when the support surface 121a is a substrate support surface and the thickness t of the electrostatic chuck 121 is 4.6 mm, the aspect ratio is 23 or more. As another example, when the support surface 121a is a ring support surface and the thickness t of the electrostatic chuck 121 is 2.8 mm, the aspect ratio is 14 or more.

A lower limit of the diameter φ of the heat transfer gas supply hole 210 is not particularly limited, and may be, for example, 0.01 mm or more as a lower limit of a diameter that can be formed by water laser processing, which will be described later.

FIG. 6 is a plan view illustrating a modification of the number and disposition of the heat transfer gas supply holes 210 in the gas outlet 203. Four heat transfer gas supply holes 210 according to the modification are formed for each gas outlet 203, and these heat transfer gas supply holes 210 are provided at rotationally symmetrical positions in the plan view of the electrostatic chuck 121. A cross-sectional shape of the heat transfer gas supply hole 210 according to the modification is an elliptical shape in the cross-section perpendicular to the flow path direction of the heat transfer gas supply hole 210. The diameter φ of the heat transfer gas supply hole 210 according to the modification is a minor axis of an ellipse in the cross-sectional shape.

In another modification, a cross-sectional shape of the heat transfer gas supply hole 210 is a slit shape in the cross-section perpendicular to the flow path direction of the heat transfer gas supply hole 210. The term “slit shape” refers to a shape that includes one or more pairs of parallel straight lines or parallel curved lines within a shape thereof, such as a square, a rectangle, or a rounded rectangle, or a shape in which a pair of parallel straight lines included in these shapes is replaced with parallel curved lines. A diameter φ in the slit shape is a distance between two lines of the parallel straight line or the parallel curve. By forming the cross-sectional shape of the heat transfer gas supply hole 210 in a slit shape, conductance of the heat transfer gas may be improved while maintaining a functional effect of preventing or reducing an abnormal discharge.

The conductive member 124 is, for example, a conductive ceramic. The conductive ceramic is formed, for example, by mixing a metal carbide into aluminum oxide (Al₂O₃) and baking. The metal carbide is, for example, tungsten carbide (WC), tantalum carbide (TaC), molybdenum carbide (MoC), silicon carbide (SiC), or titanium carbide (TIC). The conductive member 124 is, for example, metal.

By forming the conductive member 124 integrally with the dielectric member 122, an installation tolerance that may occur in the embedded member such as in Patent Document 1 can be prevented, and a dimension of the gap G between the substrate W and the electrostatic chuck 121 can be strictly designed.

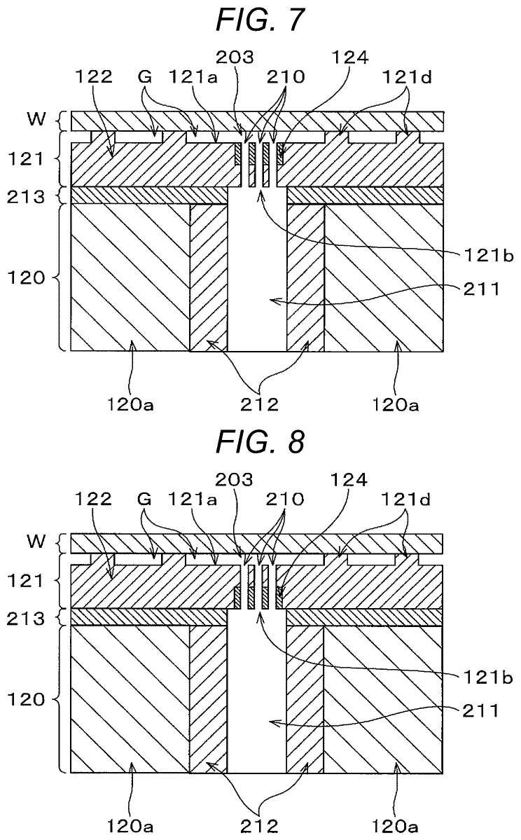

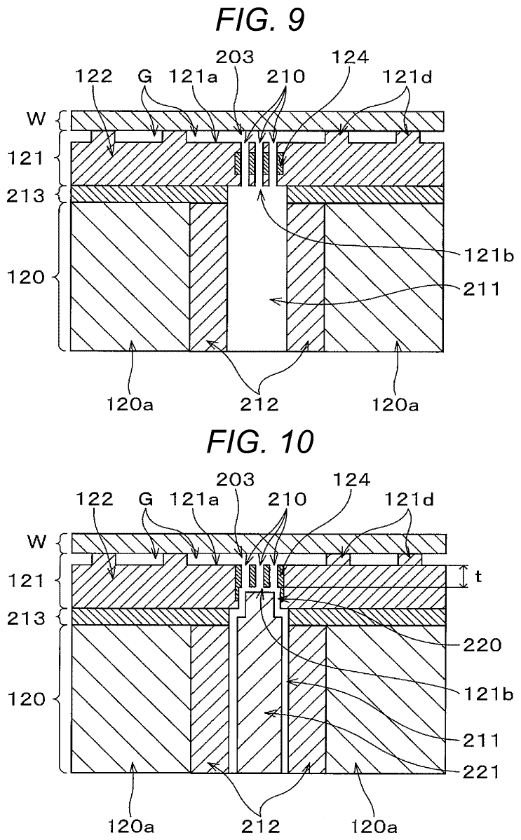

The conductive member 124 may be provided not only around the entire heat transfer gas supply hole 210 but also around only a portion of the heat transfer gas supply hole 210. FIGS. 7 to 9 illustrate a modification in which the conductive member 124 is provided around a portion of the heat transfer gas supply hole 210. As illustrated in FIG. 7, the conductive member 124 may be disposed around an end of the heat transfer gas supply hole 210 near the support surface 121a. As illustrated in FIG. 8, the conductive member 124 may be disposed around an end of the heat transfer gas supply hole 210 near the rear surface 121b. As illustrated in FIG. 9, the conductive member 124 may be disposed around an intermediate portion between the end near the support surface 121a and the end near the rear surface 121b of the heat transfer gas supply hole 210, instead of being disposed around the ends.

In one embodiment, the heat transfer gas supplied from the heat transfer gas source 201 passes through the base flow path 211 and the heat transfer gas supply hole 210, and reaches the gap G between the substrate W and the electrostatic chuck 121.

In one embodiment, the conductive member 124 is provided to be divided into a plurality of portions in a circumferential direction and/or a vertical direction. In this case, each of the divided conductive members 124 is electrically connected by vias or wiring.

### Second Embodiment

Hereinafter, a configuration example of the main body 111 according to a second embodiment will be described. FIG. 10 is a partial cross-sectional view schematically illustrating the configuration example of the main body 111 according to the second embodiment. Among configurations of the main body 111 according to the second embodiment, description of a configuration same as that in the first embodiment will be omitted. Modifications described in the first embodiment can also be adopted in the second embodiment.

In FIG. 10, the electrostatic chuck 121 has a recess 220 having a diameter larger than the diameter of each heat transfer gas supply hole 210 at a position corresponding to the base flow path 211. The recess 220 forms a portion of the rear surface 121b opposite to the support surface 121a. The heat transfer gas supply hole 210 penetrates from the support surface 121a to the rear surface 121b of the recess 220. Accordingly, the heat transfer gas supply hole 210, the recess 220, and the base flow path 211 communicate with each other, and these form the heat transfer gas flow path 202 according to the second embodiment. A diameter of the recess 220 may be the same as or different from that of the base flow path 211.

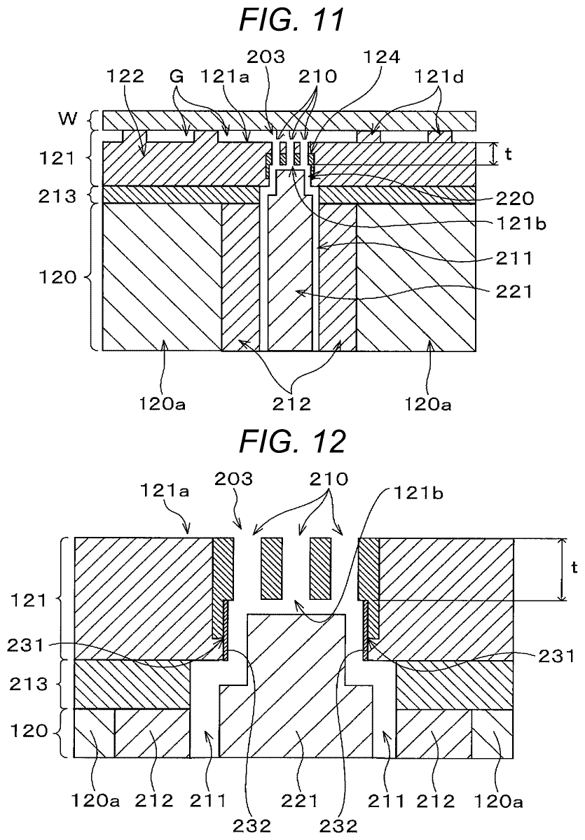

The conductive member 124 is disposed around the entire heat transfer gas supply hole 210. In one embodiment, similar to the modification illustrated in FIGS. 7 to 9 described above, the conductive member 124 may be disposed around an end of the heat transfer gas supply hole 210 near the support surface 121a, an end of the heat transfer gas supply hole 210 near the rear surface 121b, or an intermediate portion of the heat transfer gas supply hole 210. FIG. 11 is a modification in which the conductive member 124 is provided around the end of the heat transfer gas supply hole 210 near the rear surface 121b.

The conductive member 124 is disposed around at least a portion of the recess 220 from an end of the recess 220 on a side communicating with the heat transfer gas supply hole 210 to an end of the recess 220 on a side communicating with the base flow path 211. In the present embodiment, the conductive member 124 is disposed around the end on the side communicating with the heat transfer gas supply hole 210. In one embodiment, the conductive member 124 provided around the heat transfer gas supply hole 210 and the conductive member 124 disposed around at least a portion of the recess 220 may be the integrated conductive member 124.

An embedded member 221 is provided in the base flow path 211 and/or the heat transfer gas flow path 202 in the recess 220. The embedded member 221 is made of, for example, a resin or a ceramic. The embedded member 221 is provided so as to be separated from the inner wall of the base flow path 211 and/or an inner wall of the recess 220 and fill a space in the base flow path 211 and/or the recess 220. Accordingly, a flow path cross-sectional area of the heat transfer gas flow path 202 is reduced. According to the embedded member 221, for example, a heat transfer gas flows in a narrow region between the embedded member 221 and the sleeve 212, so that an occurrence of abnormal discharge in the base flow path 211 can be prevented or reduced. Further, the occurrence of abnormal discharge in the heat transfer gas supply hole 210 can be more effectively prevented or reduced.

In one embodiment, an insulating layer 232 that covers at least a boundary 231 between the conductive member 124 and the dielectric member 122 is formed on the inner wall of the recess 220. FIG. 12 is a modification in which the insulating layer 232 that covers the boundary 231 is formed. In the modification illustrated in FIG. 12, the insulating layer 232 is formed to cover the entire inner wall of the recess 220 that includes the boundary 231. The insulating layer 232 may be a coating of an insulating material applied to the inner wall of the recess 220, or may be an insulating film formed on an upper surface of the inner wall of the recess 220. The insulating layer 232 prevents an edge of the conductive member 124 at the boundary 231 from being exposed to the heat transfer gas flow path 202, and prevents a steep gradient of the electric field from occurring around the boundary 231. Accordingly, the occurrence of abnormal discharge in the heat transfer gas supply hole 210 or the recess 220 can be more effectively prevented or reduced.

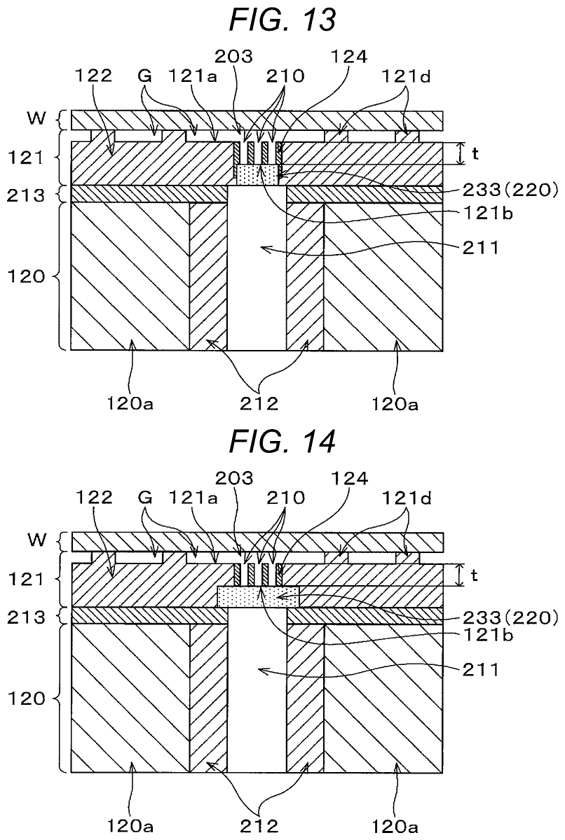

In one embodiment, the base flow path 211 and/or the recess 220 are provided with a porous member 233 instead of the embedded member 221 or in addition to the embedded member 221. FIGS. 13 and 14 illustrate a modification in which the porous member 233 is provided in the recess 220 instead of the embedded member 221. In FIG. 13, the porous member 233 is provided in contact with an inner wall of the recess 220 to fill a space in the recess 220. In FIG. 14, the electrostatic chuck 121 is provided with the recess 220 having a diameter larger than the diameter of the base flow path 211, and the porous member 233 is provided in contact with the inner wall of the recess 220 to fill the space in the recess 220.

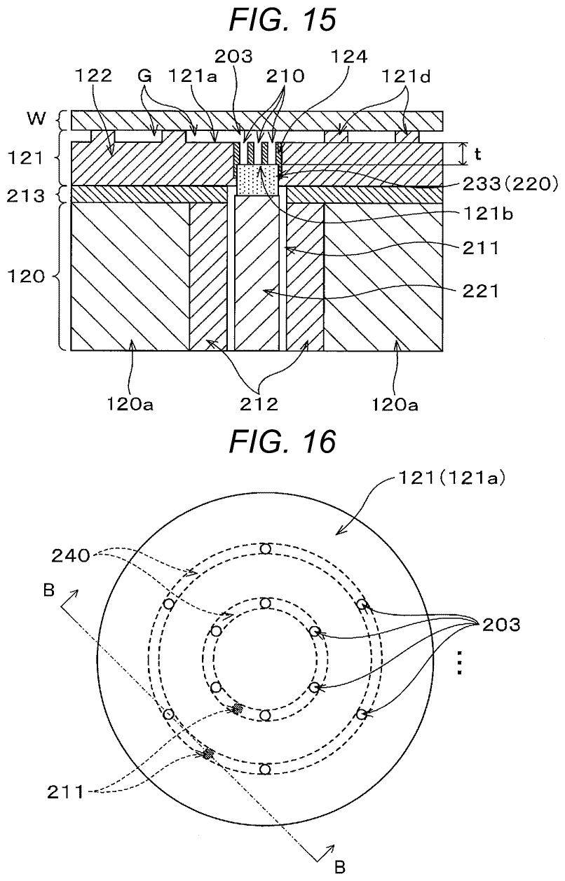

FIG. 15 illustrates a modification in which the embedded member 221 and the porous member 233 are provided in the base flow path 211 and the recess 220. The embedded member 221 is separated from the inner wall of the base flow path 211 and is provided to fill the space in the base flow path 211. The porous member 233 is provided in contact with the inner wall of the recess 220, and is provided to fill the space in the recess 220 and a part of the space in the base flow path 211.

The porous member 233 is an open-cell porous body made of, for example, alumina (Al₂O₃), or silicon carbide (SiC). A pore diameter of the porous member 233 is, for example, 300 μm or less.

When the porous member 233 fills the space in the recess 220, a space where an abnormal discharge may occur may be reduced or eliminated, and the occurrence of abnormal discharge in the heat transfer gas supply hole 210 or the recess 220 may be more effectively prevented or reduced.

Here, a diameter φ of the heat transfer gas supply hole 210 is the same as that in the first embodiment, but in the second embodiment, it is further preferable that an aspect ratio of the heat transfer gas supply hole 210 is 7 or more. The aspect ratio of the heat transfer gas supply hole 210 is a ratio (t/φ) of a thickness t of the electrostatic chuck 121 to the diameter q of the heat transfer gas supply hole 210. The thickness t of the electrostatic chuck 121 refers to a distance from the support surface 121a to the rear surface 121b of the electrostatic chuck 121, excluding the dots 121d. As an example, when the support surface 121a is a substrate support surface and the thickness t of the electrostatic chuck 121 is 2.3 mm, the aspect ratio is 11.5 or more. As another example, when the support surface 121a is a ring support surface, the thickness t of the electrostatic chuck 121 is 1.4 mm, and the diameter φ of the heat transfer gas supply hole 210 is 0.2 μm, the aspect ratio is 7 or more. When the aspect ratio of the heat transfer gas supply hole 210 is set to 7 or more, the occurrence of abnormal discharge in the heat transfer gas supply hole 210 or the recess 220 can be more effectively prevented or reduced.

It is considered that since the recess 220 is formed in the second embodiment, the thickness t of the electrostatic chuck 121 is smaller than that in the first embodiment. Even in this case, by setting the aspect ratio to 7 or more, the occurrence of abnormal discharge in the heat transfer gas supply hole 210 or the recess 220 can be prevented or reduced.

### Third Embodiment

Hereinafter, a configuration example of the main body 111 according to a third embodiment will be described. FIG. 16 is a plan view schematically illustrating the configuration example of the main body 111 according to the third embodiment. FIG. 17 is a partial cross-sectional view taken perpendicular to the support surface 121a along a section B-B in FIG. 16, schematically illustrating the configuration example of the main body 111 according to the third embodiment. Among configurations of the main body 111 according to the third embodiment, description of a configuration same as that described in the first embodiment or the second embodiment will be omitted. Modifications described in the first embodiment or second embodiment can also be adopted in the third embodiment.

In FIGS. 16 and 17, at least one distribution flow path 240 is formed for a plurality of gas outlets 203 on an upper surface of the base 120 according to the third embodiment. In the present embodiment, one distribution flow path 240 is formed for each of six gas outlets 203 disposed on each of two concentric circles, as illustrated in FIG. 16. At least one base flow path 211 is connected to one distribution flow path 240. The distribution flow path 240 is formed to extend in an in-plane direction of the upper surface of the base 120 to connect the base flow path 211 and ends of a plurality of heat transfer gas supply holes 210 near the rear surface 121b to communicate with each other. As illustrated in FIG. 17, the adhesive layer 213 has a hole having a diameter same as that of the heat transfer gas supply hole 210 to connect and communicate the heat transfer gas supply hole 210 and the base flow path 211. Accordingly, the heat transfer gas supply hole 210, the distribution flow path 240, and the base flow path 211 communicate with each other, and these form the heat transfer gas flow path 202 according to the third embodiment.

In the present embodiment, the distribution flow path 240 is formed to extend annularly in the in-plane direction of the base 120, but present disclosure is not limited thereto, and the distribution flow path 240 may be formed, for example, to extend radially and rotationally symmetrically with a center of the base 120 as an origin.

By providing the distribution flow path 240, a plurality of gas outlets 203 can be provided for one base flow path 211, and a space where an abnormal discharge may occur can be reduced. In the heat transfer gas flow path 202, a distance in a thickness direction of the electrostatic chuck 121, which is a direction in which electrons are accelerated by an electric field generated in the main body 111, can be shortened.

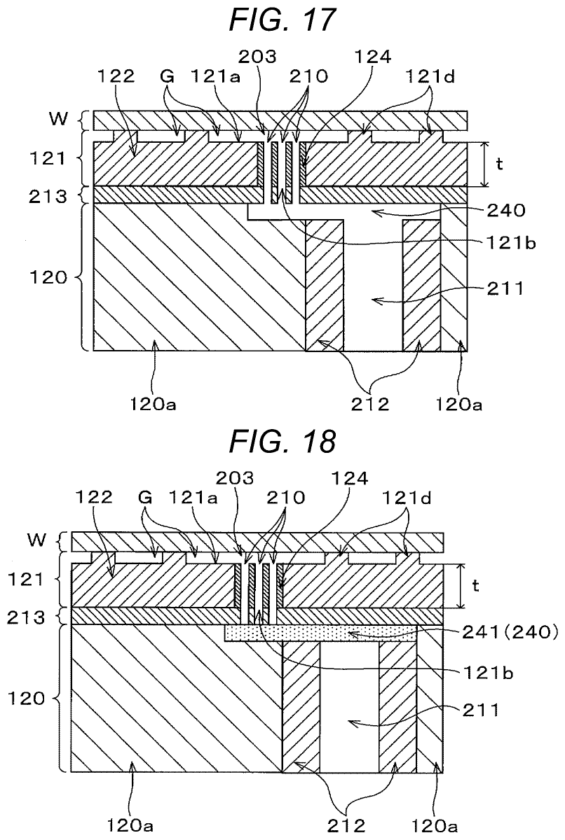

FIG. 18 illustrates a modification in which a porous member 241 is provided in the distribution flow path 240. In the modification, the porous member 241 is provided in contact with an inner wall of the distribution flow path 240 to fill a space of the distribution flow path 240. When the porous member 241 fills the space in the distribution flow path 240, the space where an abnormal discharge may occur can be reduced, and thus, the occurrence of abnormal discharge in the heat transfer gas supply hole 210 or the distribution flow path 240 can be more effectively prevented or reduced.

### Fourth Embodiment

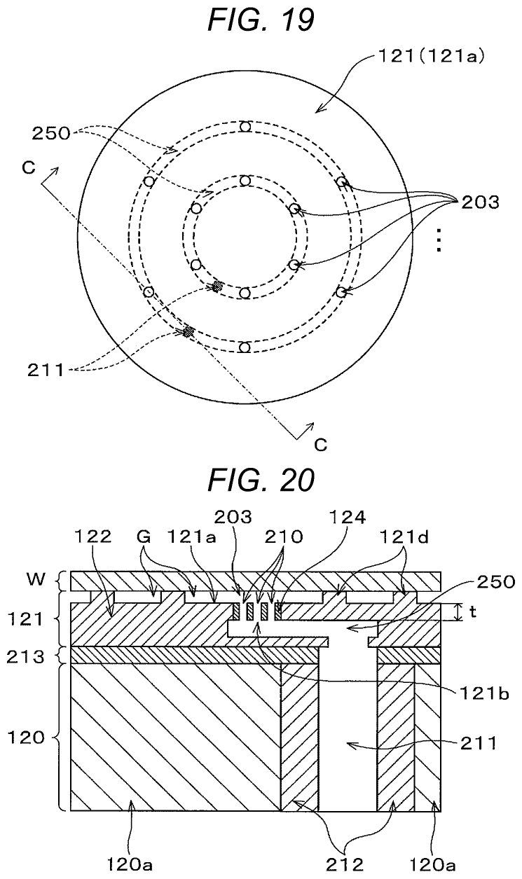

Hereinafter, a configuration example of the main body 111 according to a fourth embodiment will be described. FIG. 19 is a plan view schematically illustrating the configuration example of the main body 111 according to the fourth embodiment. FIG. 20 is a partial cross-sectional view taken perpendicular to the support surface 121a along a section C-C in FIG. 19, schematically illustrating the configuration example of the main body 111 according to the fourth embodiment. Among configurations of the main body 111 according to the fourth embodiment, description of a configuration same as that described in any of the first embodiment to the third embodiment will be omitted. Modifications described in any of the first embodiment to the third embodiment can also be adopted in the fourth embodiment.

In FIGS. 19 and 20, at least one distribution flow path 250 is formed for a plurality of gas outlets 203 in the electrostatic chuck 121 according to the fourth embodiment. In the present embodiment, one distribution flow path 250 is formed for each of six gas outlets disposed on each of two concentric circles, as illustrated in FIG. 19. At least one base flow path 211 is connected to one distribution flow path 250. The distribution flow path 250 forms a portion of the rear surface 121b opposite to the support surface 121a. The heat transfer gas supply hole 210 penetrates from the support surface 121a to the rear surface 121b of the distribution flow path 250. The distribution flow path 250 is formed to extend in an in-plane direction inside the electrostatic chuck 121 to connect the base flow path 211 and ends of a plurality of heat transfer gas supply holes 210 near the rear surface 121b so as to communicate with each other. Accordingly, the heat transfer gas supply hole 210, the distribution flow path 250, and the base flow path 211 communicate with each other, and these form the heat transfer gas flow path 202 according to the fourth embodiment.

By providing the distribution flow path 250, a plurality of gas outlets 203 can be provided for one base flow path 211, and a space where an abnormal discharge may occur can be reduced. In the heat transfer gas flow path 202, a distance in a thickness direction of the electrostatic chuck 121, which is a direction in which electrons are accelerated by an electric field generated in the main body 111, can be shortened. Accordingly, an occurrence of abnormal discharge can be prevented or reduced.

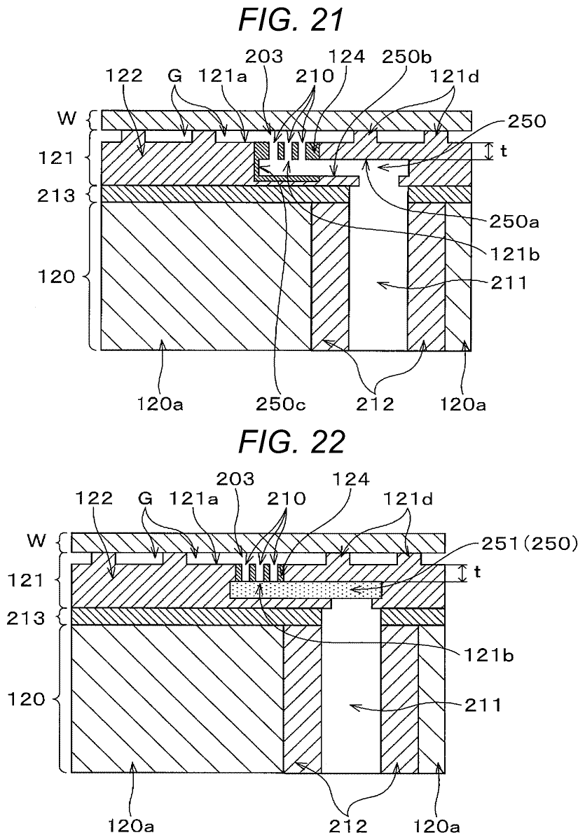

FIG. 21 illustrates a modification in which the conductive member 124 is disposed around at least a portion of the distribution flow path 250. In the modification, the conductive member 124 is disposed around the distribution flow path 250 in the vicinity of a portion connected to the heat transfer gas supply hole 210. In one embodiment, the conductive member 124 provided around at least a portion of the heat transfer gas supply hole 210 and the conductive member 124 disposed around at least a portion of the distribution flow path 250 may be the integrated conductive member 124. In one embodiment, the conductive member 124 is disposed around an entire inner wall of the distribution flow path 250.

FIG. 22 illustrates a modification in which the porous member 251 is provided in the distribution flow path 250. In the modification, the porous member 251 is provided in contact with an inner wall of the distribution flow path 250 to fill a space in the distribution flow path 250. When the porous member 251 fills the space in the distribution flow path 250, the space where an abnormal discharge may occur can be reduced, and thus, the occurrence of abnormal discharge in the heat transfer gas supply hole 210 or the distribution flow path 250 can be more effectively prevented or reduced.

### <Conductive Embedded Member>

### Fifth Embodiment

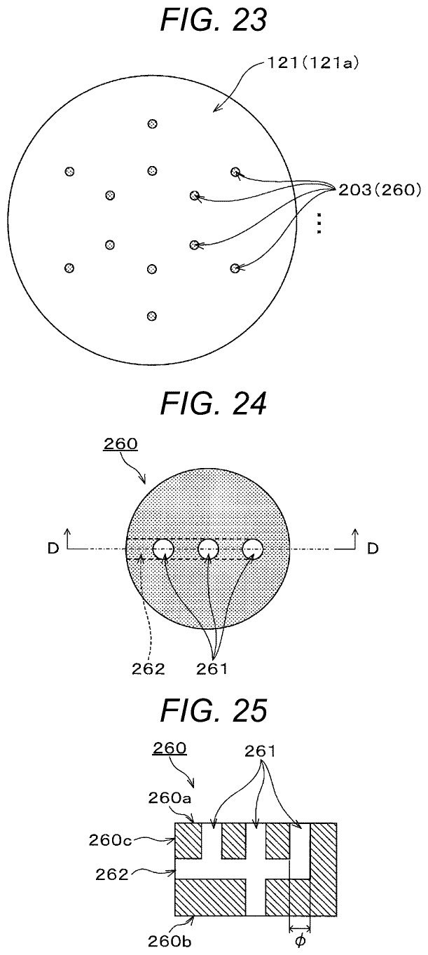

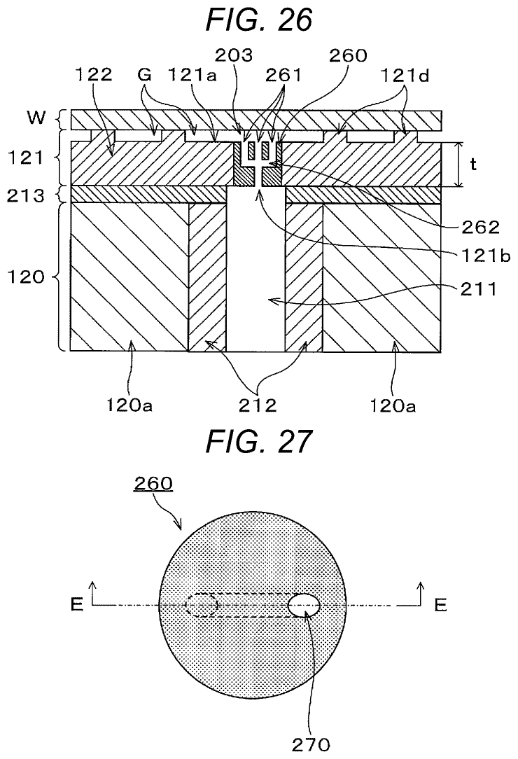

Hereinafter, a configuration example of a conductive embedded member 260 according to a fifth embodiment will be described. FIG. 23 is a plan view schematically illustrating a configuration example of the main body 111 provided with the conductive embedded member 260 according to the fifth embodiment. FIG. 24 is a plan view illustrating the configuration example of the conductive embedded member 260 according to the fifth embodiment. FIG. 25 is a cross-sectional view of the conductive embedded member 260 according to the fifth embodiment taken along a section D-D in FIG. 24. FIG. 26 is a partial cross-sectional view schematically illustrating the configuration example of the main body 111 provided with the conductive embedded member 260 according to the fifth embodiment.

In FIG. 23, the electrostatic chuck 121 according to the fifth embodiment has a hole penetrating from the support surface 121a of the electrostatic chuck 121 to the rear surface 121b opposite to the support surface 121a in the gas outlet 203. The conductive embedded member 260 is embedded in the hole.

In FIGS. 24 and 25, the conductive embedded member 260 is a substantially cylindrical member having an upper surface 260a, a lower surface 260b, and a side surface 260c. The conductive embedded member 260 has a vertical hole 261 or a horizontal hole 262. The vertical hole 261 includes a hole penetrating from the upper surface 260a to the lower surface 260b and a hole penetrating from the upper surface 260a to the horizontal hole 262. The horizontal hole 262 allows a plurality of the vertical holes 261 to communicate with each other inside the conductive embedded member 260.

In FIG. 26, the conductive embedded member 260 according to the fifth embodiment is embedded in the hole provided in the electrostatic chuck 121, thereby achieving a functional effect similar to that of at least the conductive member 124 and the heat transfer gas supply hole 210 around which the conductive member 124 is provided, which have been described in the first to fourth embodiments. That is, a substrate of the conductive embedded member 260 acts as the conductive member 124, and the vertical hole 261 and the horizontal hole 262 act as the heat transfer gas supply hole 210 by connecting the gap G between the substrate W and the electrostatic chuck 121 to the base flow path 211.

From such a viewpoint, the conductive embedded member 260 has a configuration similar to that of the conductive member 124 and the heat transfer gas supply hole 210 around which the conductive member 124 is provided, which have been described in the first to fourth embodiments. That is, similar to the conductive member 124, the conductive embedded member 260 is made of, for example, a conductive ceramic. The conductive ceramic is formed, for example, by mixing a metal carbide into aluminum oxide (Al₂O₃) and baking. The metal carbide is, for example, tungsten carbide (WC), tantalum carbide (TaC), molybdenum carbide (MoC), silicon carbide (SiC), or titanium carbide (TIC).

A diameter φ of each of the vertical hole 261 and the horizontal hole 262 is 0.5 mm or less, and is 0.2 mm or less in one embodiment.

In one embodiment, the conductive embedded member 260 has a recess or distribution flow path similar to a part or all of the recess 220 or the distribution flow path 250, and achieves a functional effect similar to that of the recess 220 or distribution flow path 250 around which the conductive member 124 is provided according to the second to fourth embodiments.

FIGS. 27 and 28 illustrate a modification of the conductive embedded member 260. FIG. 27 is a plan view illustrating a modification of the conductive embedded member 260. FIG. 28 is a cross-sectional view of the conductive embedded member 260 taken along a section E-E in FIG. 27. In the modification, an inclined hole 270 is formed instead of the vertical hole 261 and the horizontal hole 262. The inclined hole 270 is formed such that a flow path axis L is inclined at a desired angle with respect to the upper surface 260a or the lower surface 260b. A cross-sectional shape of the inclined hole 270 in a direction orthogonal to the flow path axis L is substantially circular. In this case, a diameter φ of the inclined hole 270 is a diameter of a circle in the cross-section in the direction orthogonal to the flow path axis L. The diameter φ of the inclined hole 270 is 0.5 mm or less, and is 0.2 mm or less in one embodiment. In one embodiment, a plurality of inclined holes 270 are provided.

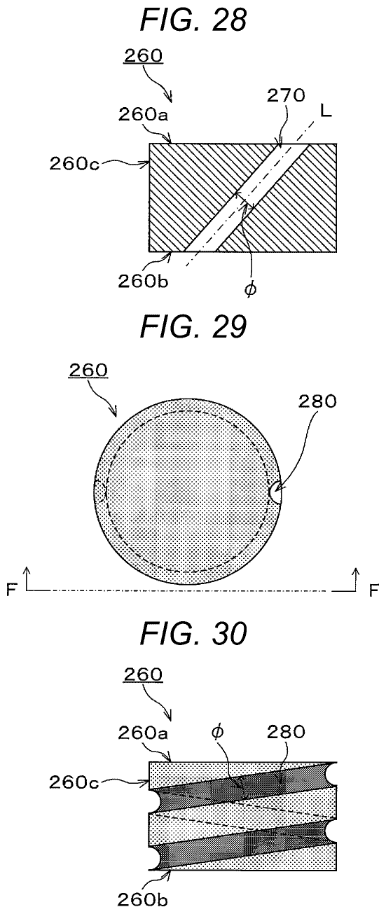

FIGS. 29 and 30 illustrate another modification of the conductive embedded member 260. FIG. 29 is a plan view illustrating another modification of the conductive embedded member 260. FIG. 30 is a side view of the conductive embedded member 260 viewed from an F-F direction in FIG. 29. In the modification, a helical groove 280 is formed instead of the vertical hole 261 and the horizontal hole 262. The helical groove 280 is helically formed by digging a groove on the side surface 260c, extending from one point on a peripheral edge of the upper surface 260a, through the side surface 260c, to one point on a peripheral edge of the lower surface 260b. When the conductive embedded member 260 having the helical groove 280 is embedded in a hole penetrating from the support surface 121a of the electrostatic chuck 121 to the rear surface 121b opposite to the support surface 121a, an inner surface of the hole and the side surface 260c of the conductive embedded member 260 come into close contact with each other, and as a result, the inner surface of the hole and the helical groove 280 form the heat transfer gas supply hole 210. A diameter φ of the helical groove 280 is a groove width. The diameter φ of the helical groove 280 is 0.5 mm or less, and is 0.2 mm or less in one embodiment. In one embodiment, a plurality of helical grooves 280 are provided.

According to the conductive embedded member 260 according to the fifth embodiment, a portion of the electrostatic chuck 121 corresponding to the conductive member 124 can be processed and manufactured separately. In processing the conductive embedded member 260, design flexibility of a shape and an angle of the hole is higher than that for the conductive member 124 integrally formed with the electrostatic chuck 121. Accordingly, the hole (the vertical hole 261, the horizontal hole 262, the inclined hole 270, or the helical groove 280) can be formed such that a distance in a thickness direction of the electrostatic chuck 121, which is a direction in which electrons are accelerated by the electric field generated in the main body 111, becomes shorter. Accordingly, an occurrence of abnormal discharge in the heat transfer gas supply hole 210 can be more effectively prevented or reduced. Since a size of the embedded part is small, a degree of difficulty of performing installation is low, and a manufacturing cost can be reduced additionally.

### <Electrical Connection Between Conductive Member and Base>

### Sixth Embodiment

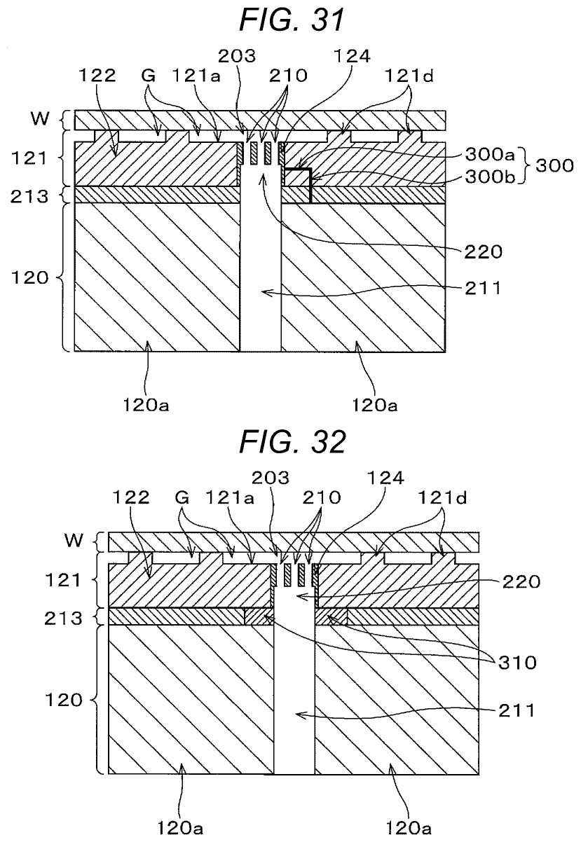

Hereinafter, a configuration example of the main body 111 according to a sixth embodiment will be described. FIG. 31 is a partial cross-sectional view schematically illustrating the configuration example of the main body 111 according to the sixth embodiment. In the following description, the conductive embedded member 260 according to the fifth embodiment is included in the conductive member 124. Among configurations of the main body 111 according to the sixth embodiment, description of a configuration similar to that described in the first to fifth embodiments will be omitted. Modifications described in the first embodiment to the fifth embodiment can also be adopted in the sixth embodiment.

The main body 111 according to the sixth embodiment includes a short-circuit member 300. The short-circuit member 300 is a conductive member provided to connect the base 120 and the electrostatic chuck 121. The short-circuit member 300 includes a horizontal portion 300a and a vertical portion 300b. The horizontal portion 300a is provided to be electrically connected to at least one location of the conductive member 124. The vertical portion 300b is electrically connected to the horizontal portion 300a and the base 120, and can extend through the adhesive layer 213.

The short-circuit member 300 electrically connects the conductive member 124 and the base 120. In the present embodiment, the conductive member 124 and the base 120 are short-circuited by the short-circuit member 300, and the conductive member 124 and the base 120 have the same potential. Accordingly, since an electric field-free space is formed in the base flow path 211 and the recess 220, an occurrence of abnormal discharge in the base flow path 211 and the recess 220 can be more effectively prevented or reduced.

From such a viewpoint, in one embodiment, the base flow path 211 and the heat transfer gas flow path 202 related to the recess 220 are formed to be thinner than that in a related-art example. For example, diameters of the base flow path 211 and the recess 220 are set to be the same and are set to 4.0 mm or less. Accordingly, due to the above-described electric field-free space, an occurrence of abnormal discharge can be prevented or reduced while also preventing or reducing an occurrence of temperature singularities of the substrate W and/or edge ring during plasma processing. In one embodiment, a configuration is adopted in which no embedded member 221 is provided to fill a space in the base flow path 211 and the heat transfer gas flow path 202 related to the recess 220. In one embodiment, a configuration is adopted in which the base flow path 211 does not have the sleeve 212. Accordingly, due to the above-described electric field-free space, a manufacturing cost can be additionally reduced while maintaining the action of preventing or reducing the occurrence of abnormal discharge.

In one embodiment, the horizontal portion 300a of the short-circuit member 300 may be connected to a plurality of locations. The short-circuit member 300 may be connected such that the horizontal portion 300a surrounds an entire periphery of the conductive member 124. The horizontal portion 300a may be connected to a portion of the periphery of the conductive member 124. The horizontal portion 300a may be disposed at any height as long as it is connected to the conductive member 124. Further, the horizontal portion 300a may be connected to the conductive member 124 disposed around the heat transfer gas supply hole 210, instead of the conductive member 124 disposed around the recess 220. In this case, an electrostatic electrode and/or an RF/DC electrode disposed in the electrostatic chuck 121 may be avoided. Further, the horizontal portion 300a may be connected to the conductive member 124 disposed around the distribution flow path 250, instead of the conductive member 124 disposed around the recess 220.

The short-circuit member 300 according to the present embodiment includes the horizontal portion 300a and the vertical portion 300b, and may have any shape as long as a short-circuit between the conductive member 124 and the base 120 can be implemented.

### Seventh Embodiment

Hereinafter, a configuration example of the main body 111 according to a seventh embodiment will be described. FIG. 32 is a partial cross-sectional view schematically illustrating the configuration example of the main body 111 according to the seventh embodiment. In FIG. 32, the adhesive layer 213 includes a short-circuit adhesive layer 310. An end of the conductive member 124 near the adhesive layer 213 is short-circuited with the base 120 via the short-circuit adhesive layer 310. The short-circuit adhesive layer 310 is, for example, a conductive adhesive or a metal braze. Accordingly, a short circuit between the conductive member 124 and the base 120 can be implemented without using the short-circuit member 300.

### Eighth Embodiment

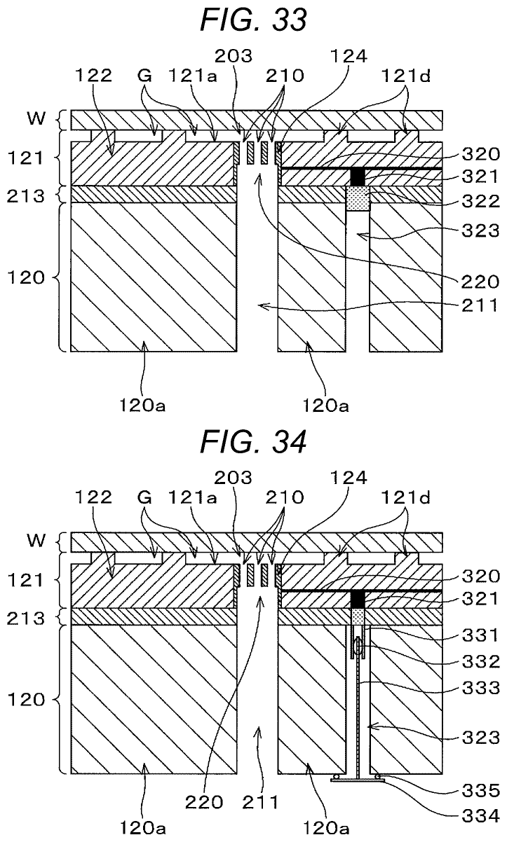

Hereinafter, a configuration example of the main body 111 according to an eighth embodiment will be described. FIG. 33 is a partial cross-sectional view schematically illustrating the configuration example of the main body 111 according to the eighth embodiment. In FIG. 33, the conductive member 124 is short-circuited with the base 120 via an electrode layer 320, a via 321, and a bonding member 322. The bonding member 322 is, for example, a conductive adhesive or a metal braze. The bonding member 322 is disposed in a through-hole 323. The bonding member 322 may have any shape as long as it can conduct with the electrode layer 320, the via 321, and the base 120. The electrode layer 320 may serve as any one of an electrostatic electrode, an RF/DC electrode, and a heater electrode, to the extent that the function is not impaired. In one embodiment, the through-hole 323 and the bonding member 322 are disposed near a center of the base 120 so as to be less affected by a difference in thermal expansion between the base 120 and the electrostatic chuck 121.

### Ninth Embodiment

Hereinafter, a configuration example of the main body 111 according to a ninth embodiment will be described. FIG. 34 is a partial cross-sectional view schematically illustrating the configuration example of the main body 111 according to the ninth embodiment. In FIG. 34, the conductive member 124 is short-circuited with the base 120 via the electrode layer 320, the via 321, and a fixed pin assembly. The fixed pin assembly includes a fitting portion 331, a pin elastic 332 to be inserted into the through-hole 323, a pin including a pin shaft 333 and a pin head 334, and an elastic connector 335. The electrode layer 320 may serve as any one of an electrostatic electrode, an RF/DC electrode, and a heater electrode, to the extent that the function is not impaired.

The fitting portion 331, the pin elastic 332, the pin shaft 333, the pin head 334, and the elastic connector 335 are all formed of a conductive member, and are electrically conductive with each other. The pin head 334 is electrically connected to the base 120 via the elastic connector 335. The fitting portion 331 is electrically connected to the via 321.

Accordingly, the conductive member 124 is short-circuited with the base 120 via the electrode layer 320, the via 321, and the fixed pin assembly. The pin elastic 332 and/or the elastic connector 335 may be a desired conductive member that elastically connects the pin head 334 and the base 120, such as a plate spring, a disc spring, or a coil spring.

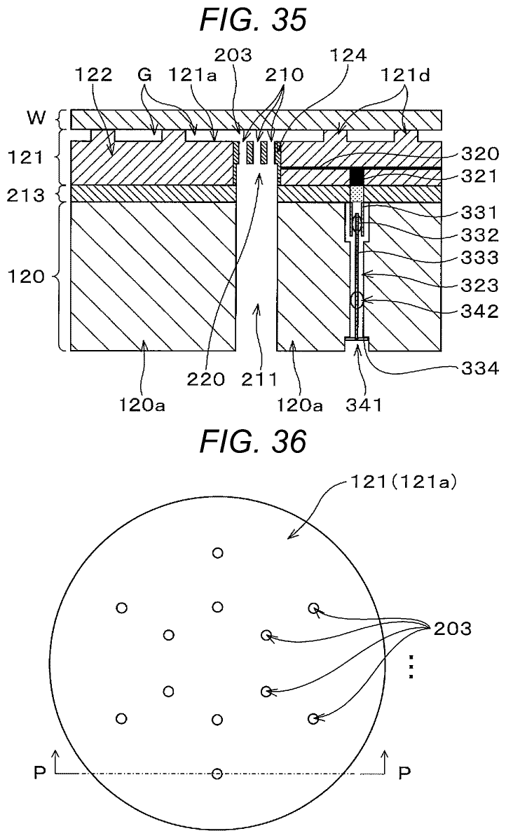

FIG. 35 illustrates one modification of the main body 111 according to the ninth embodiment. In the modification illustrated in FIG. 35, the base 120 has a recess 341 on the base 120 near a lower surface in the through-hole 323. The pin head 334 engages with the recess 341. The pin shaft 333 is provided with a pin shaft elastic connector 342. The pin shaft elastic connector 342 is formed of a conductive member and electrically communicates with other components of the fixed pin assembly. The pin shaft elastic connector 342 comes into contact with the base 120 to electrically connect the pin shaft 333 and the base 120. Accordingly, the conductive member 124 is short-circuited with the base 120 via the electrode layer 320, the via 321, and the fixed pin assembly. The pin shaft elastic connector 342 may be a desired conductive member that elastically connects the pin shaft 333 and the base 120, such as a plate spring, a disc spring, or a coil spring.

### Tenth Embodiment

Hereinafter, a configuration example of the main body 111 according to a tenth embodiment will be described. In the main body 111 according to the tenth embodiment, the conductive member 124 is connected to an electrode layer provided in the electrostatic chuck 121. The electrode layer and the conductive base 120a of the base 120 are each connected to the power source 30, for example. For example, the controller 2 controls the electrode layer and the conductive base 120a such that they are at the same potential. Accordingly, the conductive member 124 connected to the electrode layer and the base 120 are at the same potential, and an electric field-free space is formed inside the heat transfer gas supply hole 210 and the base flow path 211 around which the conductive member 124 is disposed, thereby more effectively preventing or reducing an occurrence of abnormal discharge in the heat transfer gas supply hole 210 and the base flow path 211.

### <Method for Forming Heat Transfer Gas Supply Hole>

As an example, the heat transfer gas supply hole 210 according to the first embodiment to the ninth embodiment described above can be formed by water laser processing (also referred to as water jet laser processing or water beam laser processing).

In the water laser processing, a jet stream of water or liquid is ejected toward the conductive member 124 or the conductive embedded member 260 in the electrostatic chuck 121, and a laser beam is caused to advance while being confined within the jet stream based on the principle of an optical fiber. Then, at an end of the jet stream, processing is performed by the laser beam, and the jet stream cools a portion where a processed hole is formed and exhausts processing waste.

In related art, in processing of the heat transfer gas flow path 202 in the electrostatic chuck 121 or the like, there has been known a method for forming the heat transfer gas flow path 202 by performing processing such as machining center processing (MC processing), water jet processing, or electric discharge processing. The MC processing or water jet processing cannot process holes with a high aspect ratio above a certain level, and tends to result in a tapered shape. The electric discharge processing has a disadvantage that a processing time is very long. The “water jet processing” simply involves spraying high-pressure water onto an object, and is different from the water laser processing.

In contrast, according to the water laser processing, a hole having a high aspect ratio can be formed in a short time, and a diameter φ of the heat transfer gas supply hole 210 can be formed to be 0.5 mm or less. According to the water laser processing, the heat transfer gas supply hole 210 can be formed to have a diameter φ of 0.2 mm or less and an aspect ratio of 7 or more, which are preferable configurations. As an example, the water laser processing can be performed using a laser processing machine “Luminizer LB300/LB500” manufactured by Makino Milling Machine Co., Ltd. (“Makino Milling Machine Co., Ltd.” and “Luminizer” are registered trademarks).

### OTHER EMBODIMENTS

In the above-described embodiments of the present disclosure, by providing the conductive member 124 around at least the heat transfer gas supply hole 210, the main body 111 of the substrate support 11 is provided that can prevent or reduce an occurrence of abnormal discharge at least in at least a portion of the heat transfer gas supply hole 210. Even when the conductive member 124 is not provided around the heat transfer gas supply hole 210, the occurrence of abnormal discharge can be prevented or reduced by setting a diameter φ of the heat transfer gas supply hole 210 to 0.2 mm or less and setting an aspect ratio to 7 or more. Hereinafter, the main body 111 according to an embodiment in which no conductive member 124 is provided around the heat transfer gas supply hole 210 will be described. In the following embodiments, description of a configuration same as that described in the above embodiment will be omitted.

### Eleventh Embodiment

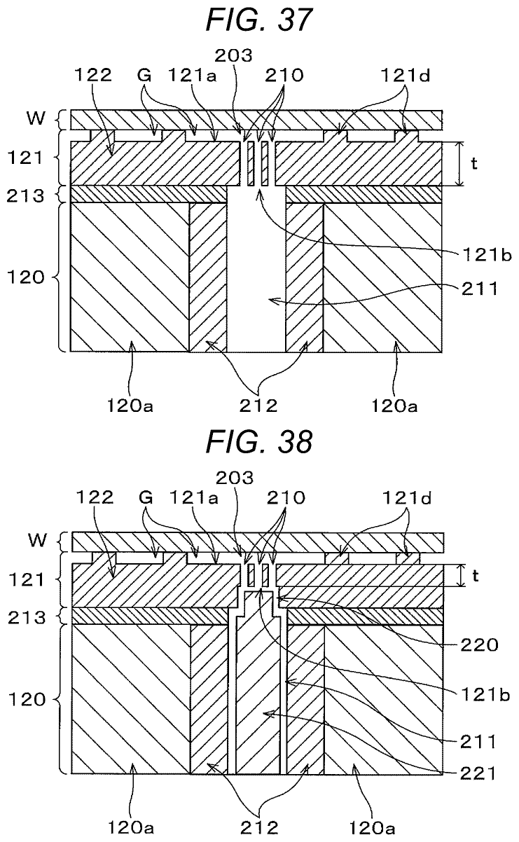

FIG. 36 is a plan view schematically illustrating a configuration example of the main body 111 according to an eleventh embodiment. FIG. 37 is a partial cross-sectional view taken perpendicular to the support surface 121a along a section P-P in FIG. 36, schematically illustrating the configuration example of the main body 111 according to the eleventh embodiment.

In the eleventh embodiment, the heat transfer gas supply hole 210 is formed in the dielectric member 122 in the gas outlet 203. In addition, a configuration same as that of the main body 111 according to the first embodiment is provided, except that no conductive member 124 is provided around the heat transfer gas supply hole 210.

In the main body 111 according to the eleventh embodiment, when a diameter φ of the heat transfer gas supply hole 210 is set to 0.2 mm or less and an aspect ratio is set to 7 or more, an occurrence of abnormal discharge can be prevented or reduced.

### Twelfth Embodiment

FIG. 38 is a partial cross-sectional view schematically illustrating a configuration example of the main body 111 according to a twelfth embodiment. In the twelfth embodiment, the heat transfer gas supply hole 210 is formed in the dielectric member 122 in the gas outlet 203. In addition, a configuration same as that of the main body 111 according to the second embodiment is provided, except that no conductive member 124 is provided around the heat transfer gas supply hole 210.

In the main body 111 according to the twelfth embodiment, when a diameter φ of the heat transfer gas supply hole 210 is set to 0.2 mm or less and an aspect ratio is set to 7 or more, an occurrence of abnormal discharge can be prevented or reduced. According to the embedded member 221, a flow path cross-sectional area of the heat transfer gas flow path 202 is reduced. Accordingly, for example, a heat transfer gas flows in a narrow region between the embedded member 221 and the sleeve 212, so that the occurrence of abnormal discharge in the heat transfer gas supply hole 210 and/or the base flow path 211 can be prevented or reduced.

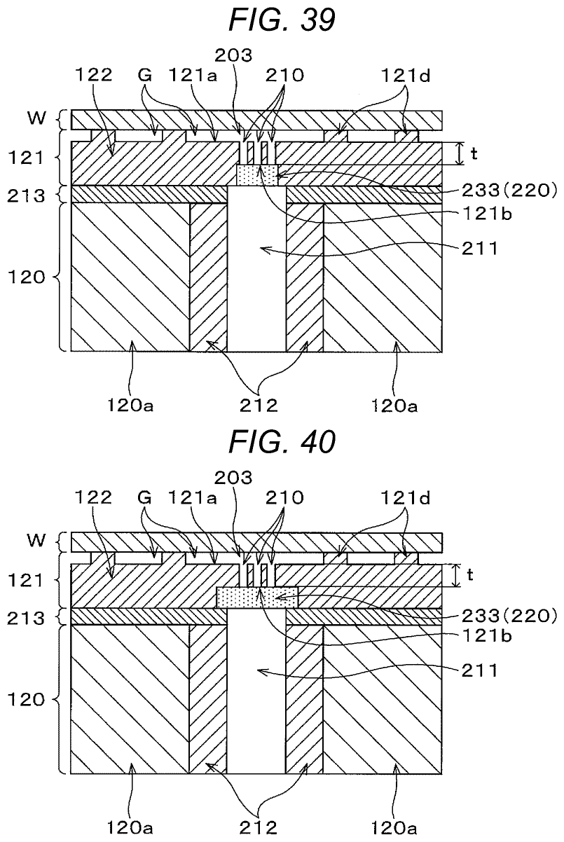

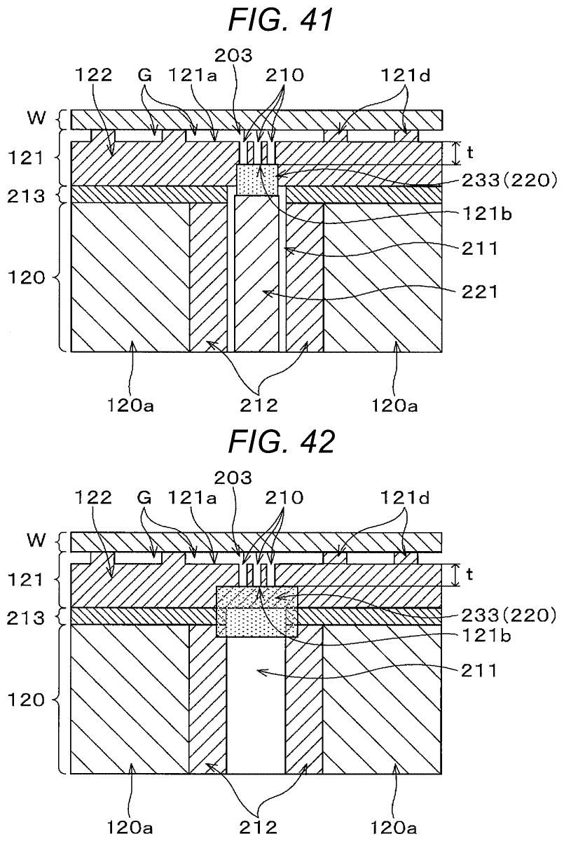

FIGS. 39 to 42 are partial cross-sectional views schematically illustrating a configuration example of the main body 111 according to a modification of the twelfth embodiment. In the modification of the twelfth embodiment, the heat transfer gas supply hole 210 is formed in the dielectric member 122 in the gas outlet 203. In addition, a configuration same as that of the main body 111 according to the embodiment described using FIGS. 13 to 15 as a modification of the second embodiment is provided, except that no conductive member 124 is provided around the heat transfer gas supply hole 210.

In the main body 111 according to the modification of the twelfth embodiment, when a diameter φ of the heat transfer gas supply hole 210 is set to 0.2 mm or less and an aspect ratio is set to 7 or more, an occurrence of abnormal discharge can be prevented or reduced. When the porous member 233 fills a space in the recess 220, a space where an abnormal discharge may occur may be reduced or eliminated, and the occurrence of abnormal discharge in the heat transfer gas supply hole 210 or the recess 220 can be more effectively prevented or reduced.

### Thirteenth Embodiment

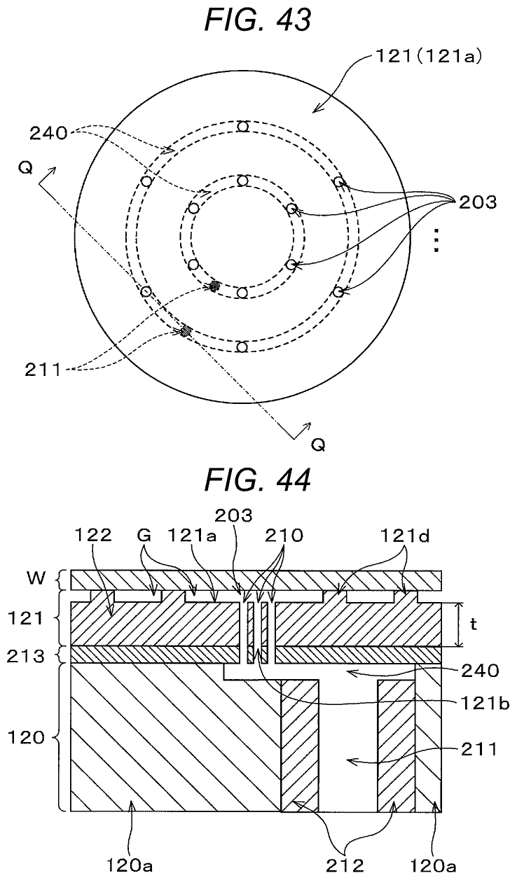

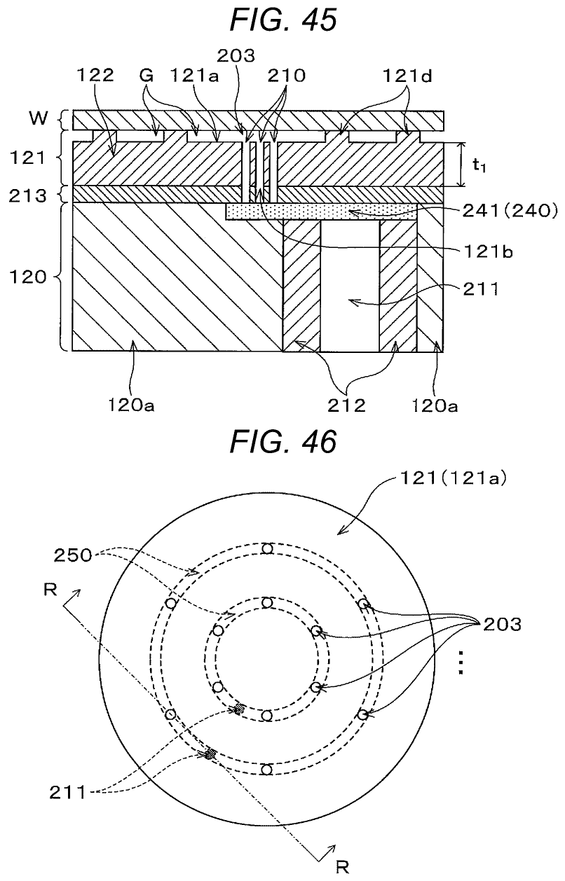

FIG. 43 is a plan view schematically illustrating a configuration example of the main body 111 according to a thirteenth embodiment. FIG. 44 is a partial cross-sectional view taken perpendicular to the support surface 121a along a section Q-Q in FIG. 43, schematically illustrating the configuration example of the main body 111 according to the thirteenth embodiment. FIG. 45 is a partial cross-sectional view schematically illustrating a configuration example of the main body 111 according to a modification of the thirteenth embodiment.

In the thirteenth embodiment, the heat transfer gas supply hole 210 is formed in the dielectric member 122 in the gas outlet 203. In addition, a configuration same as that of the main body 111 according to the third embodiment or the main body 111 according to the embodiment described with reference to FIG. 18 as a modification of the third embodiment is provided, except that no conductive member 124 is provided around the heat transfer gas supply hole 210.

In the main body 111 according to the thirteenth embodiment, when a diameter φ of the heat transfer gas supply hole 210 is set to 0.2 mm or less and an aspect ratio is set to 7 or more, an occurrence of abnormal discharge can be prevented or reduced. By providing the distribution flow path 240, a plurality of gas outlets 203 can be provided for one base flow path 211, and a space where an abnormal discharge may occur can be reduced. In the heat transfer gas flow path 202, a distance in a thickness direction of the electrostatic chuck 121, which is a direction in which electrons are accelerated by an electric field generated in the main body 111, can be shortened. Accordingly, an occurrence of abnormal discharge can be prevented or reduced. In the modification illustrated in FIG. 45, when the porous member 233 fills a space in the distribution flow path 240, a space where an abnormal discharge may occur may be reduced or eliminated, and the occurrence of abnormal discharge in the heat transfer gas supply hole 210 or the distribution flow path 240 can be more effectively prevented or reduced.

### Fourteenth Embodiment

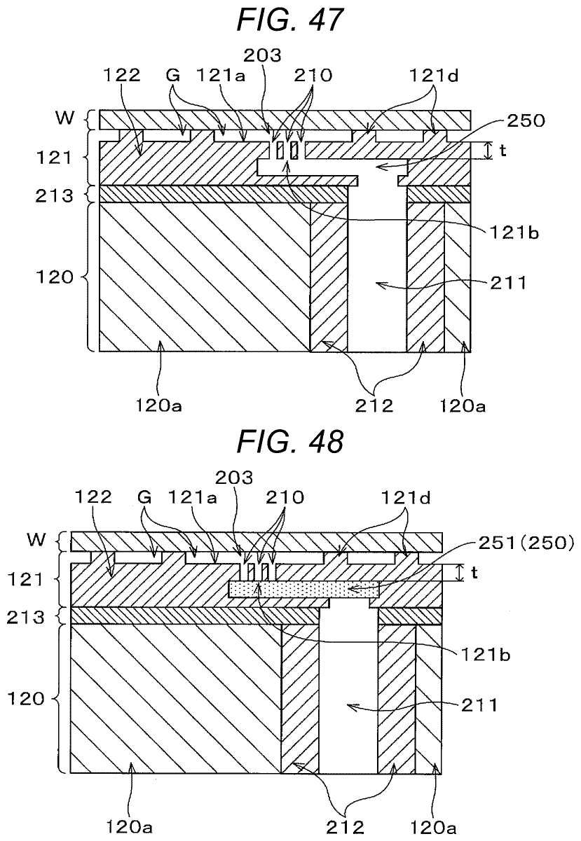

FIG. 46 is a plan view schematically illustrating a configuration example of the main body 111 according to a fourteenth embodiment. FIG. 47 is a partial cross-sectional view taken perpendicular to the support surface 121a along a section R-R in FIG. 46, schematically illustrating the configuration example of the main body 111 according to the fourteenth embodiment. FIG. 48 is a partial cross-sectional view schematically illustrating a configuration example of the main body 111 according to a modification of the fourteenth embodiment.

In the fourteenth embodiment, the heat transfer gas supply hole 210 is formed in the dielectric member 122 in the gas outlet 203. In addition, a configuration same as that of the main body 111 according to the fourth embodiment or the main body 111 according to the embodiment described with reference to FIG. 22 as a modification of the fourth embodiment is provided, except that no conductive member 124 is provided around the heat transfer gas supply hole 210.

In the main body 111 according to the fourteenth embodiment, when a diameter φ of the heat transfer gas supply hole 210 is set to 0.2 mm or less and an aspect ratio is set to 7 or more, an occurrence of abnormal discharge can be prevented or reduced. By providing the distribution flow path 250, a plurality of gas outlets 203 can be provided for one base flow path 211, and a space where an abnormal discharge may occur can be reduced. In the heat transfer gas flow path 202, a distance in a thickness direction of the electrostatic chuck 121, which is a direction in which electrons are accelerated by an electric field generated in the main body 111, can be shortened. Accordingly, an occurrence of abnormal discharge can be prevented or reduced. In the modification illustrated in FIG. 48, when the porous member 251 fills a space in the distribution flow path 250, a space where an abnormal discharge may occur may be reduced or eliminated, and the occurrence of abnormal discharge in the heat transfer gas supply hole 210 or the distribution flow path 250 can be more effectively prevented or reduced.

### Fifteenth Embodiment

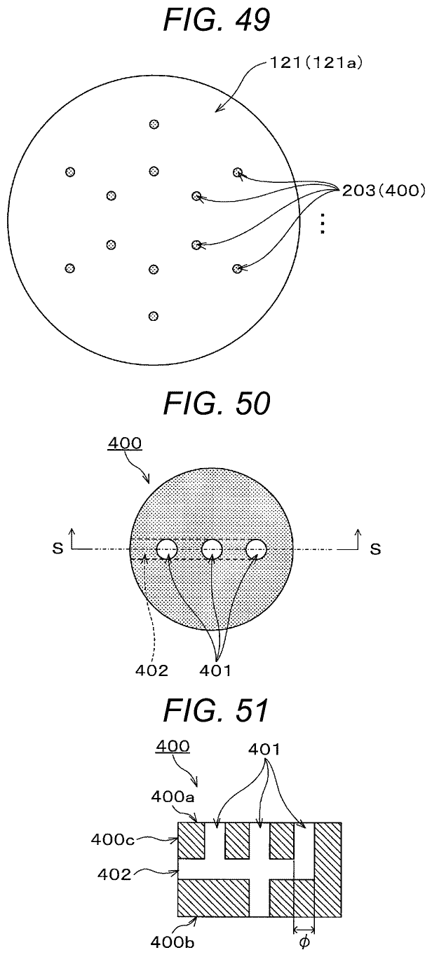

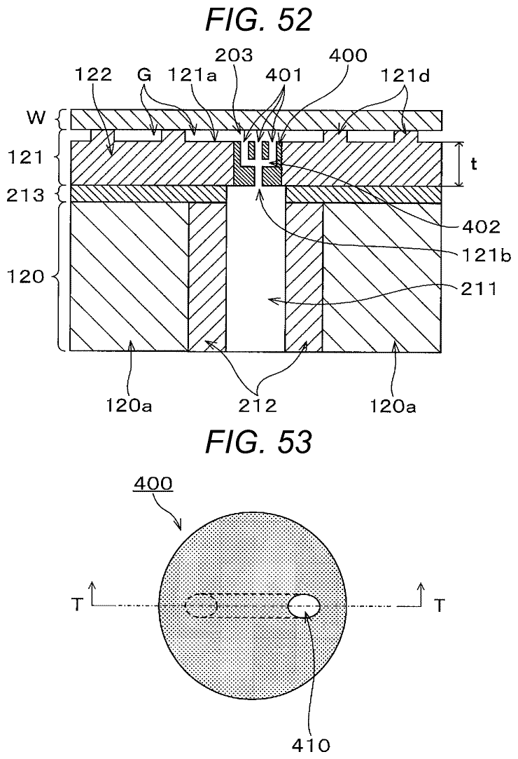

FIG. 49 is a plan view schematically illustrating a configuration example of the main body 111 provided with an embedded member 400 according to a fifteenth embodiment. FIG. 50 is a plan view illustrating a configuration example of the embedded member 400 according to the fifteenth embodiment. FIG. 51 is a cross-sectional view of the embedded member 400 according to the fifteenth embodiment taken along a section S-S in FIG. 50. FIG. 52 is a partial cross-sectional view schematically illustrating the configuration example of the main body 111 provided with the embedded member 400 according to the fifteenth embodiment. In the fifteenth embodiment, a configuration same as that of the main body 111 according to the fifth embodiment is provided, except that the embedded member 400 is not conductive.

In FIG. 49, the electrostatic chuck 121 according to the fifteenth embodiment is provided with a hole penetrating from the support surface 121a of the electrostatic chuck 121 to the rear surface 121b opposite to the support surface 121a in the gas outlet 203. The embedded member 400 is embedded in the hole.

In FIGS. 50 and 51, the embedded member 400 is a substantially cylindrical member having an upper surface 400a, a lower surface 400b, and a side surface 400c. The embedded member 400 has a vertical hole 401 or a horizontal hole 402. The vertical hole 401 includes a hole penetrating from the upper surface 400a to the lower surface 400b and a hole penetrating from the upper surface 400a to the horizontal hole 402. The horizontal hole 402 allows a plurality of the vertical holes 401 to communicate with each other inside the embedded member 400.

In FIG. 52, the embedded member 400 according to the fifteenth embodiment is embedded in the hole provided in the electrostatic chuck 121, thereby achieving at least a functional effect same as that of the heat transfer gas supply hole 210 described in the eleventh embodiment to the fourteenth embodiment. That is, the vertical hole 401 and the horizontal hole 402 acts as the heat transfer gas supply hole 210 by connecting the gap G between the substrate W and the electrostatic chuck 121 to the base flow path 211. From such a viewpoint, a diameter q of the vertical hole 401 and the horizontal hole 402 is 0.2 mm or less, similar to that of the heat transfer gas supply hole 210 according to the eleventh to fourteenth embodiments. Further, an aspect ratio is 7 or more.

In one embodiment, a recess or a distribution flow path similar to a part or all of the recess 220 or the distribution flow path 250 is formed in the embedded member 400, and achieves a functional effect same as that of the recess 220 or distribution flow path 250 according to the twelfth embodiment to the fourteenth embodiment.

In one embodiment, the embedded member 400 is made of, for example, an insulating ceramic.

FIGS. 53 and 54 illustrate a modification of the embedded member 400. FIG. 53 is a plan view illustrating the modification of the embedded member 400. FIG. 54 is a cross-sectional view of the embedded member 400 taken along a section T-T in FIG. 53. In the modification, an inclined hole 410 is formed instead of the vertical hole 401 and the horizontal hole 402. The inclined hole 410 is formed such that a flow path axis L is inclined at a desired angle with respect to the upper surface 400a or the lower surface 400b. The inclined hole 410 has a substantially circular cross-sectional shape in a direction orthogonal to the flow path axis L. In this case, a diameter φ of the inclined hole 410 is a diameter of a circle in the cross-section in the direction orthogonal to the flow path axis L. The diameter φ of the inclined hole 410 is 0.5 mm or less, and is 0.2 mm or less in one embodiment. In one embodiment, a plurality of inclined holes 410 are provided.

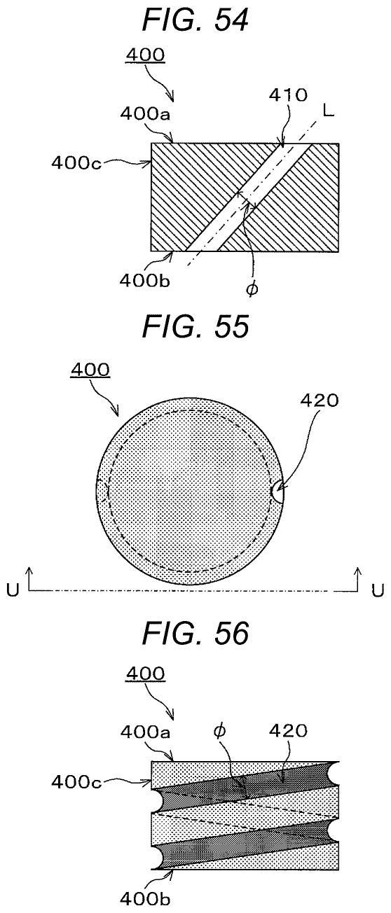

FIGS. 55 and 56 illustrate another modification of the embedded member 400. FIG. 55 is a plan view illustrating the other modification of the embedded member 400. FIG. 56 is a side view of the embedded member 400 viewed from an F-F direction in FIG. 55. In the modification, a helical groove 420 is formed instead of the vertical hole 401 and the horizontal hole 402. The helical groove 420 is helically formed by digging a groove on the side surface 400c, extending from one point on a peripheral edge of the upper surface 400a, through the side surface 400c, to one point on a peripheral edge of the lower surface 400b. When the embedded member 400 having the helical groove 420 is embedded in a hole penetrating from the support surface 121a of the electrostatic chuck 121 to the rear surface 121b opposite to the support surface 121a, an inner surface of the hole and the side surface 400c of the embedded member 400 come into close contact with each other, and as a result, the inner surface of the hole and the helical groove 420 form the heat transfer gas supply hole 210. A diameter φ of the helical groove 420 is a groove width. The diameter φ of the helical groove 420 is 0.5 mm or less, and is 0.2 mm or less in one embodiment. In one embodiment, a plurality of helical grooves 420 are provided.

According to the embedded member 400 according the fifteenth embodiment, the gas outlet 203 provided in the dielectric member 122 of the electrostatic chuck 121 can be processed and manufactured separately. In processing of the embedded member 400, design flexibility of a shape and an angle of the hole is higher than that in direct processing of the dielectric member 122 of the electrostatic chuck 121. Accordingly, the hole (the vertical hole 401, the horizontal hole 402, the inclined hole 410, or the helical groove 420) can be formed such that a distance in a thickness direction of the electrostatic chuck 121, which is a direction in which electrons are accelerated by the electric field generated in the main body 111, becomes shorter. Accordingly, an occurrence of abnormal discharge in the heat transfer gas supply hole 210 can be more effectively prevented or reduced. Since a size of the embedded part is small, a degree of difficulty of installation is low, and a manufacturing cost can be additionally reduced compared to the main body 111 according to the eleventh embodiment to the fourteenth embodiment.

It shall be understood that the embodiments disclosed herein are illustrative and are not restrictive in all aspects. The embodiment described above may be omitted, replaced, or modified in various forms without departing from the scope and spirit of the appended claims. For example, the components of the embodiments described above may be combined as desired. From the desired combination, functions and effects of each component related to the combination can be obtained as a matter of course, and other functions and effects apparent to those skilled in the art can be obtained from the description herein.

The effects described herein are merely illustrative or exemplary, and are not limited. In other words, the technique according to the present disclosure may have other effects apparent to those skilled in the art from the description herein, in addition to or in place of the effects described above.

The following configuration examples also fall within the technical scope of the present disclosure.

(1) A plasma processing apparatus, including:
a plasma processing chamber,
a base disposed in the plasma processing chamber, and
an electrostatic chuck disposed on an upper surface of the base and having a support surface that supports at least one of a substrate and a ring assembly, in which
the electrostatic chuck includes at least one conductive member,
the electrostatic chuck is formed with at least one heat transfer gas supply hole having a diameter of 0.2 mm or less and penetrating from the support surface to a rear surface opposite to the support surface, and
the at least one conductive member is disposed around at least a portion of the heat transfer gas supply hole.

(2) The plasma processing apparatus according to the above (1), in which
the base is formed with a base flow path communicating with the heat transfer gas supply hole,
the electrostatic chuck is formed with a recess having a diameter larger than the diameter of the heat transfer gas supply hole at a position corresponding to the base flow path, and
the heat transfer gas supply hole penetrates from the support surface to the rear surface in the recess.

(3) The plasma processing apparatus according to the above (2), further including:
at least one embedded member disposed in at least one of the base flow path and the recess.

(4) The plasma processing apparatus according to the above (3), in which
the at least one embedded member has a porous structure.

(5) The plasma processing apparatus according to the above (4), in which
the at least one conductive member is disposed around at least a portion of the recess.

(6) The plasma processing apparatus according to the above (5), in which
the conductive member disposed around the recess includes an insulator layer forming an inner wall around the recess.

(7) The plasma processing apparatus according to the above (1), in which
the base is formed with a base flow path communicating with the heat transfer gas supply hole and a distribution flow path extending in an in-plane direction of the upper surface of the base and connecting the base flow path and ends of a plurality of the heat transfer gas supply holes near the rear surface to communicate with each other.

(8) The plasma processing apparatus according to the above (7), further including:
at least one embedded member disposed in at least one of the base flow path and the distribution flow path.

(9) The plasma processing apparatus according to the above (8), in which
the at least one embedded member has a porous structure.

(10) The plasma processing apparatus according to the above (1), in which
the base is formed with a base flow path communicating with the heat transfer gas supply hole,
the electrostatic chuck is formed with a distribution flow path extending in an in-plane direction of the electrostatic chuck and connecting the base flow path and ends of a plurality of the heat transfer gas supply holes near the rear surface to communicate with each other, and
the heat transfer gas supply hole penetrates from the support surface to the rear surface in the distribution flow path.

(11) The plasma processing apparatus according to the above (10), further including:
an embedded member disposed in at least one of the base flow path and the distribution flow path.

(12) The plasma processing apparatus according to the above (11), in which
the embedded member has a porous structure.

(13) The plasma processing apparatus according to any one of the above (10) to (12), in which
the at least one conductive member is disposed around the heat transfer gas supply hole in the distribution flow path.

(14) The plasma processing apparatus according to any one of the above (10) to (13), in which
the at least one conductive member is disposed around the entire distribution flow path.

(15) The plasma processing apparatus according to any one of the above (1) to (9), in which
the at least one conductive member is disposed around an end of the heat transfer gas supply hole near the support surface.

(16) The plasma processing apparatus according to any one of the above (1) to (9), in which
the at least one conductive member is disposed around an end of the heat transfer gas supply hole near the rear surface.

(17) The plasma processing apparatus according to any one of the above (1) to (16), in which
a cross-sectional shape of the heat transfer gas supply hole is an elliptical shape, a rectangular shape, or a slit shape, the diameter of the cross-sectional shape being 0.2 mm or less.

(18) The plasma processing apparatus according to the above (17), in which
an aspect ratio of the heat transfer gas supply hole is 7 or more, the aspect ratio being the diameter of the cross-sectional shape to a thickness of the electrostatic chuck.

(19) The plasma processing apparatus according to any one of the above (1) to (18), in which
the conductive member is electrically connected to the base.

(20) A substrate support for supporting at least one of a substrate and a ring assembly in a plasma processing chamber, the substrate support including:
an electrostatic chuck having a support surface that supports at least one of the substrate and the ring assembly, in which
the electrostatic chuck includes at least one conductive member,
the electrostatic chuck is formed with at least one heat transfer gas supply hole having a diameter of 0.2 mm or less and penetrating from the support surface to a rear surface opposite to the support surface, and
the at least one conductive member is disposed around at least a portion of the heat transfer gas supply hole.

(21) The substrate support according to the above (20), further including:
a base on which the electrostatic chuck is disposed on an upper surface thereof, in which
the base is formed with a base flow path communicating with the heat transfer gas supply hole,
the electrostatic chuck is formed with a recess having a diameter larger than the diameter of the heat transfer gas supply hole at a position corresponding to the base flow path, and
the heat transfer gas supply hole penetrates from the support surface to the rear surface in the recess.

(22) The substrate support according to the above (21), further including:
at least one embedded member disposed in at least one of the base flow path and the recess.

(23) The substrate support according to the above (22), in which
the at least one embedded member has a porous structure.

(24) The substrate support according to the above (23), in which
the at least one conductive member is disposed around at least a portion of the recess.

(25) The substrate support according to the above (24), in which
the conductive member disposed around the recess includes an insulator layer forming an inner wall around the recess.

(26) The substrate support according to the above (20), in which
the base is formed with a base flow path communicating with the heat transfer gas supply hole and a distribution flow path extending in an in-plane direction of the upper surface of the base and connecting the base flow path and ends of a plurality of the heat transfer gas supply holes near the rear surface to communicate with each other.

(27) The substrate support according to the above (26), further including:
at least one embedded member disposed in at least one of the base flow path and the distribution flow path.

(28) The substrate support according to the above (27), in which
the at least one embedded member has a porous structure.

(29) The substrate support according to the above (20), in which
the base is formed with a base flow path communicating with the heat transfer gas supply hole,
the electrostatic chuck is formed with a distribution flow path extending in an in-plane direction of the electrostatic chuck and connecting the base flow path and ends of a plurality of the heat transfer gas supply holes near the rear surface to communicate with each other, and
the heat transfer gas supply hole penetrates from the support surface to the rear surface in the distribution flow path.

(30) The substrate support according to the above (29), further including:
an embedded member disposed in at least one of the base flow path and the distribution flow path.

(31) The substrate support according to the above (30), in which
the embedded member has a porous structure.

(32) The substrate support according to any one of the above (29) to (31), in which
the at least one conductive member is disposed around the heat transfer gas supply hole in the distribution flow path.

(33) The substrate support according to any one of the above (29) to (31), in which
the at least one conductive member is disposed around the entire distribution flow path.

(34) The substrate support according to any one of the above (20) to (28), in which
the at least one conductive member is disposed around an end of the heat transfer gas supply hole near the support surface.

(35) The substrate support according to any one of the above (20) to (28), in which
the at least one conductive member is disposed around an end of the heat transfer gas supply hole near the rear surface.

(36) The substrate support according to any one of the above (20) to (35), in which
a cross-sectional shape of the heat transfer gas supply hole is an elliptical shape, a rectangular shape, or a slit shape, the diameter of the cross-sectional shape being 0.2 mm or less.

(37) The substrate support according to the above (36), in which
an aspect ratio of the heat transfer gas supply hole is 7 or more, the aspect ratio being the diameter of the cross-sectional shape to a thickness of the electrostatic chuck.

(38) The substrate support according to any one of the above (20) to (37), in which
the conductive member is electrically connected to the base.

1. A plasma processing apparatus, comprising:
a plasma processing chamber,
a base disposed in the plasma processing chamber, and
an electrostatic chuck disposed on an upper surface of the base and having a support surface that supports at least one of a substrate and a ring assembly, wherein
the electrostatic chuck includes:
at least one conductive member; and
at least one heat transfer gas supply hole having a diameter of 0.2 mm or less, the at least one heat transfer gas supply hole penetrating from the support surface to a rear surface opposite to the support surface, and
the at least one conductive member is disposed around at least a portion of the at least one heat transfer gas supply hole.

2. The plasma processing apparatus according to claim 1, wherein
the base includes a base flow path communicating with the at least one heat transfer gas supply hole,
the electrostatic chuck further includes a recess having a diameter larger than the diameter of the at least one heat transfer gas supply hole at a position corresponding to the base flow path, and
the at least one heat transfer gas supply hole penetrates from the support surface to the rear surface in the recess.

3. The plasma processing apparatus according to claim 2, further comprising:
at least one embedded member disposed in at least one of the base flow path and the recess, wherein
the at least one embedded member has a porous structure.

4. The plasma processing apparatus according to claim 3, wherein
the at least one conductive member is disposed around at least a portion of the recess, and
the at least one conductive member includes an insulator layer forming an inner wall around the recess.

5. The plasma processing apparatus according to claim 1, wherein
the base includes a base flow path communicating with the at least one heat transfer gas supply hole and a distribution flow path extending in an in-plane direction of the upper surface of the base,
the at least one heat transfer gas supply hole includes a plurality of heat transfer gas supply holes, and
the distribution flow path connects the base flow path and ends of the plurality of the heat transfer gas supply holes near the rear surface to communicate with each other.

6. The plasma processing apparatus according to claim 5, further comprising:
at least one embedded member disposed in at least one of the base flow path and the distribution flow path, and
the at least one embedded member has a porous structure.

7. The plasma processing apparatus according to claim 1, wherein
the base is formed with a base flow path communicating with the heat transfer gas supply hole,
the at least one heat transfer gas supply hole includes a plurality of heat transfer gas supply holes,
the electrostatic chuck is formed with a distribution flow path extending in an in-plane direction of the electrostatic chuck and connecting the base flow path and ends of the plurality of the heat transfer gas supply holes near the rear surface to communicate with each other, and
the plurality of heat transfer gas supply holes penetrate from the support surface to the rear surface in the distribution flow path.

8. The plasma processing apparatus according to claim 7, wherein
the at least one conductive member is disposed around at least one of the plurality of heat transfer gas supply holes in the distribution flow path.

9. The plasma processing apparatus according to claim 7, wherein
the at least one conductive member is disposed around the entire distribution flow path.

10. The plasma processing apparatus according to claim 1, wherein
the at least one conductive member is disposed around an end of the at least one heat transfer gas supply hole near the support surface or near the rear surface.

11. The plasma processing apparatus according to claim 1, wherein
a cross-sectional shape of the at least one heat transfer gas supply hole is an elliptical shape, a rectangular shape, or a slit shape, the diameter of the cross-sectional shape being 0.2 mm or less.

12. The plasma processing apparatus according to claim 11, wherein
an aspect ratio of the at least one heat transfer gas supply hole is 7 or more, the aspect ratio being the diameter of the cross-sectional shape to a thickness of the electrostatic chuck.

13. The plasma processing apparatus according to claim 1, wherein
the at least one conductive member is electrically connected to the base.

14. A substrate support for supporting at least one of a substrate and a ring assembly in a plasma processing chamber, the substrate support comprising:
an electrostatic chuck having a support surface that supports at least one of the substrate and the ring assembly, wherein
the electrostatic chuck includes:
at least one conductive member,
at least one heat transfer gas supply hole having a diameter of 0.2 mm or less and penetrating from the support surface to a rear surface opposite to the support surface, and
the at least one conductive member is disposed around at least a portion of the at least one heat transfer gas supply hole.

15. The substrate support according to claim 14, further comprising:
a base on which the electrostatic chuck is disposed on an upper surface thereof, wherein
the base is formed with a base flow path communicating with the at least one heat transfer gas supply hole,
the electrostatic chuck is formed with a recess having a diameter larger than the diameter of the at least one heat transfer gas supply hole at a position corresponding to the base flow path, and
the at least one heat transfer gas supply hole penetrates from the support surface to the rear surface in the recess.

16. The substrate support according to claim 15, further comprising:
at least one embedded member disposed in at least one of the base flow path and the recess and
the at least one embedded member has a porous structure.

17. The substrate support according to claim 16, wherein
the at least one conductive member is disposed around at least a portion of the recess, and
the at least one conductive member includes an insulator layer forming an inner wall around the recess.

18. The substrate support according to claim 14, wherein
the at least one heat transfer gas supply hole includes a plurality of heat transfer gas supply holes, and
the base includes:
a base flow path communicating with the plurality of heat transfer gas supply holes; and
a distribution flow path extending in an in-plane direction of the upper surface of the base and connecting the base flow path and ends of the plurality of the heat transfer gas supply holes near the rear surface to communicate with each other.

19. The substrate support according to claim 14, wherein
the at least one heat transfer gas supply hole includes a plurality of heat transfer gas supply holes, and
the base is formed with a base flow path communicating with the plurality of heat transfer gas supply holes,
the electrostatic chuck includes a distribution flow path extending in an in-plane direction of the electrostatic chuck and connecting the base flow path and ends of the plurality of the heat transfer gas supply holes near the rear surface to communicate with each other, and
the plurality of heat transfer gas supply holes penetrates from the support surface to the rear surface in the distribution flow path.

20. The substrate support according to claim 19, wherein
the at least one conductive member is disposed around at least one of the plurality of heat transfer gas supply holes in the distribution flow path.
